(19) United States
(12) Patent Application Publication
(10) Pub. No.: US 2025/0194279 A1
(43) Pub. Date: Jun. 12, 2025

(54) SOLID-STATE IMAGING DEVICE

(71) Applicant: SONY SEMICONDUCTOR SOLUTIONS CORPORATION, Kanagawa (JP)

(72) Inventors: Daiki TSUCHIYA, Kanagawa (JP); Hiroshi TAKAHASHI, Kanagawa (JP)

(73) Assignee: SONY SEMICONDUCTOR SOLUTIONS CORPORATION, Kanagawa (JP)

(21) Appl. No.: 18/843,395

(22) PCT Filed: Jan. 16, 2023
(86) PCT No.: PCT/JP2023/001036

§ 371 Date: Sep. 3, 2024

(30) Foreign Application Priority Data
Mar. 10, 2022 (JP) 2022-037313

(51) Int. Cl. H10F 39/00

(52) U.S. Cl. CPC H10F 39/807

(57) ABSTRACT

A solid-state imaging device includes: a pixel that is provided on a first surface side as a light incident side of a base body, and includes a photoelectric conversion element that converts light into electric charge; a transfer transistor that is provided on a second surface side of the base body on a side opposite to the first surface, at a position corresponding to the pixel, and has one main electrode electrically coupled to the photoelectric conversion element; a pixel isolation region that is provided in a thickness direction of the base body to surround the photoelectric conversion element and the transfer transistor, and provides electrical and optical isolation; and a coupling section that is provided at a position overlapping the pixel isolation region on the second surface side, and electrically couples a gate electrode of the transfer transistor and a control signal line to each other.

### TECHNICAL FIELD

The present disclosure relates to a solid-state imaging device.

### BACKGROUND ART

PTL 1 discloses an imaging element. The imaging element includes a CMOS (Complementary Metal Oxide Semiconductor) image sensor. In the image sensor, a groove that penetrates a substrate is used to from an isolation pattern that electrically and optically isolates pixels from each other. The pixel includes a photoelectric conversion region (photodiode) formed in the substrate and surrounded by the isolation pattern.

The photoelectric conversion region converts light into electric charge. The resulting electric charge is transferred to a pixel circuit through a transfer transistor and a floating diffusion region. A control signal line is coupled to a gate electrode of the transfer transistor. Operation of the transfer transistor is controlled on the basis of a control signal inputted through the control signal line.

### CITATION LIST

### Patent Literature

PTL 1: International Publication No. WO2019/220945

### SUMMARY OF THE INVENTION

In the imaging element described above, it is desired to reduce intensity of an electric field generated around the control signal line.

A solid-state imaging device according to an embodiment of the present disclosure includes: a pixel that is provided on a first surface side as a light incident side of a base body, and includes a photoelectric conversion element that converts light into electric charge; a transfer transistor that is provided on a second surface side of the base body on a side opposite to the first surface, at a position corresponding to the pixel, and has one main electrode electrically coupled to the photoelectric conversion element; a pixel isolation region that is provided in a thickness direction of the base body to surround the photoelectric conversion element and the transfer transistor, and provides electrical and optical isolation; and a coupling section that is provided at a position overlapping the pixel isolation region on the second surface side, and electrically couples a gate electrode of the transfer transistor and a control signal line to each other.

### BRIEF DESCRIPTION OF DRAWINGS

FIG. 1 is a circuit diagram illustrating pixels and a pixel circuit of a solid-state imaging device according to a first embodiment of the present disclosure.

FIG. 2 is a planar configuration diagram of the pixel and a transistor included in the pixel circuit illustrated in FIG. 1.

FIG. 3 is a planar configuration diagram of a state in which multiple pixels illustrated in FIG. 2 are arranged.

FIG. 4 is a vertical cross-sectional configuration diagram of the pixel and a transfer transistor illustrated in FIG. 2 (a cross-sectional view in an arrow Y direction taken along a line A-A illustrated in FIG. 2).

FIG. 5 is a vertical cross-sectional configuration diagram of the pixel and the transfer transistor illustrated in FIG. 2 (a cross-sectional view in an arrow X direction taken along a line B-B illustrated in FIG. 2).

FIG. 6 is a see-through perspective view illustrating a specific three-dimensional configuration of the pixel and the transfer transistor illustrated in FIGS. 4 and 5.

FIG. 7 is a planar configuration diagram of the pixel and the transfer transistor illustrated in FIG. 6 as viewed from an arrow Z direction.

FIG. 8 is a vertical cross-sectional configuration diagram of the pixel and the transfer transistor as viewed in the arrow Y direction taken along a line C-C illustrated in FIG. 7.

FIG. 9 is a vertical cross-sectional configuration diagram of the pixel and the transfer transistor as viewed in the arrow X direction taken along a line D-D illustrated in FIG. 7.

FIG. 10 is a cross-sectional view of a first step (a vertical cross-sectional configuration diagram corresponding to FIGS. 5 and 9) illustrating a method of manufacturing the solid-state imaging device according to the first embodiment.

FIG. 11 is a cross-sectional view of a second step.

FIG. 12 is a cross-sectional view of a third step.

FIG. 13 is a cross-sectional view of a fourth step.

FIG. 14 is a cross-sectional view of a fifth step.

FIG. 15 is a cross-sectional view of a sixth step.

FIG. 16 is a cross-sectional view of a seventh step.

FIG. 17 is a cross-sectional view of an eighth step.

FIG. 18 is a cross-sectional view of a first step (a vertical cross-sectional configuration diagram corresponding to FIGS. 5 and 9) illustrating a method of manufacturing a solid-state imaging device according to a second embodiment of the present disclosure.

FIG. 19 is a cross-sectional view of a second step.

FIG. 20 is a cross-sectional view of a third step.

FIG. 21 is a cross-sectional view of a fourth step.

FIG. 22 is a cross-sectional view of a fifth step.

FIG. 23 is a cross-sectional view of a sixth step.

FIG. 24 is a cross-sectional view of a seventh step.

FIG. 25 is a cross-sectional view of an eighth step.

FIG. 26 is a see-through perspective view corresponding to FIG. 6 and illustrating a specific three-dimensional configuration of a pixel and a transfer transistor of a solid-state imaging device according to a third embodiment of the present disclosure.

FIG. 27 is a planar configuration diagram corresponding to FIG. 7 of the pixel and the transfer transistor illustrated in FIG. 26 as viewed from the arrow Z direction.

FIG. 28 is a vertical cross-sectional configuration diagram corresponding to FIG. 8 of the pixel and the transfer transistor as viewed in the arrow Y direction taken along a line E-E illustrated in FIG. 27.

FIG. 29 is a vertical cross-sectional configuration diagram corresponding to FIG. 9 of the pixel and the transfer transistor as viewed in the arrow X direction taken along a line F-F illustrated in FIG. 27.

FIG. 30 is a see-through perspective view corresponding to FIG. 6 and illustrating a specific three-dimensional configuration of a pixel and a transfer transistor of a solid-state imaging device according to a fourth embodiment of the present disclosure.

FIG. 31 is a planar configuration diagram corresponding to FIG. 7 of the pixel and the transfer transistor illustrated in FIG. 30 as viewed from the arrow Z direction.

FIG. 32 is a vertical cross-sectional configuration diagram corresponding to FIG. 8 of the pixel and the transfer transistor as viewed in the arrow Y direction taken along a line G-G illustrated in FIG. 31.

FIG. 33 is a vertical cross-sectional configuration diagram corresponding to FIG. 9 of the pixel and the transfer transistor as viewed in the arrow X direction taken along a line H-H illustrated in FIG. 31.

FIG. 34 is a see-through perspective view corresponding to FIG. 6 and illustrating a specific three-dimensional configuration of a pixel and a transfer transistor of a solid-state imaging device according to a fifth embodiment of the present disclosure.

FIG. 35 is a planar configuration diagram corresponding to FIG. 7 of the pixel and the transfer transistor illustrated in FIG. 34 as viewed from the arrow Z direction.

FIG. 36 is a vertical cross-sectional configuration diagram corresponding to FIG. 8 of the pixel and the transfer transistor as viewed in the arrow Y direction taken along a line I-I illustrated in FIG. 35.

FIG. 37 is a vertical cross-sectional configuration diagram corresponding to FIG. 9 of the pixel and the transfer transistor as viewed in the arrow X direction taken along a line J-J illustrated in FIG. 35.

FIG. 38 is a see-through perspective view corresponding to FIG. 6 and illustrating a specific three-dimensional configuration of a pixel and a transfer transistor of a solid-state imaging device according to a sixth embodiment of the present disclosure.

FIG. 39 is a planar configuration diagram corresponding to FIG. 7 of the pixel and the transfer transistor illustrated in FIG. 38 as viewed from the arrow Z direction.

FIG. 40 is a vertical cross-sectional configuration diagram corresponding to FIG. 8 of the pixel and the transfer transistor as viewed in the arrow Y direction taken along a line K-K illustrated in FIG. 39.

FIG. 41 is a vertical cross-sectional configuration diagram corresponding to FIG. 9 of the pixel and the transfer transistor as viewed in the arrow X direction taken along a line L-L illustrated in FIG. 39.

FIG. 42 is a see-through perspective view corresponding to FIG. 6 and illustrating a specific three-dimensional configuration of a pixel and a transfer transistor of a solid-state imaging device according to a seventh embodiment of the present disclosure.

FIG. 43 is a planar configuration diagram corresponding to FIG. 7 of the pixel and the transfer transistor illustrated in FIG. 42 as viewed from the arrow Z direction.

FIG. 44 is a vertical cross-sectional configuration diagram corresponding to FIG. 8 of the pixel and the transfer transistor as viewed in the arrow Y direction taken along a line M-M illustrated in FIG. 43.

FIG. 45 is a vertical cross-sectional configuration diagram corresponding to FIG. 9 of the pixel and the transfer transistor as viewed in the arrow X direction taken along a line N-N illustrated in FIG. 43.

FIG. 46 is a planar configuration diagram corresponding to FIGS. 2 and 3 of pixels, transfer transistors, and transistors included in pixel circuits of a solid-state imaging device according to an eighth embodiment of the present disclosure as viewed from the arrow Z direction.

FIG. 47 is a planar configuration diagram corresponding to FIGS. 2 and 3 of pixels, transfer transistors, and optical lenses of a solid-state imaging device according to a ninth embodiment of the present disclosure as viewed from the arrow Z direction.

FIG. 48 is a planar configuration diagram corresponding to FIGS. 2 and 3 of pixels and transfer transistors of a solid-state imaging device according to a tenth embodiment of the present disclosure as viewed from the arrow Z direction.

FIG. 49 is a planar configuration diagram of transistors included in a pixel circuit and provided at positions corresponding to the pixels illustrated in FIG. 48 in the solid-state imaging device according to the tenth embodiment as viewed from the arrow Z direction.

FIG. 50 is a perspective view illustrating a three-dimensional configuration of a coupling section between a gate electrode of a transfer transistor and a control signal line of a solid-state imaging device according to an eleventh embodiment of the present disclosure.

FIG. 51 is a planar configuration diagram of the coupling section between the gate electrode of the transfer transistor and the control signal line illustrated in FIG. 50 as viewed from the arrow Z direction.

FIG. 52 is a side configuration diagram of the coupling section between the gate electrode of the transfer transistor and the control signal line illustrated in FIG. 50 as viewed in the arrow Y direction.

FIG. 53 is a side configuration diagram of the coupling section between the gate electrode of the transfer transistor and the control signal line illustrated in FIG. 50 as viewed in the arrow X direction.

FIG. 54 is a perspective view illustrating a three-dimensional configuration of a coupling section between a gate electrode of a transfer transistor and a control signal line of a solid-state imaging device according to a first modification example of the eleventh embodiment.

FIG. 55 is a planar configuration diagram of the coupling section between the gate electrode of the transfer transistor and the control signal line illustrated in FIG. 54 as viewed from the arrow Z direction.

FIG. 56 is a side configuration diagram of the coupling section between the gate electrode of the transfer transistor and the control signal line illustrated in FIG. 54 as viewed in the arrow Y direction.

FIG. 57 is a side configuration diagram of the coupling section between the gate electrode of the transfer transistor and the control signal line illustrated in FIG. 54 as viewed in the arrow X direction.

FIG. 58 is a perspective view illustrating a three-dimensional configuration of a coupling section between a gate electrode of a transfer transistor and a control signal line of a solid-state imaging device according to a second modification example of the eleventh embodiment.

FIG. 59 is a planar configuration diagram of the coupling section between the gate electrode of the transfer transistor and the control signal line illustrated in FIG. 58 as viewed from the arrow Z direction.

FIG. 60 is a side configuration diagram of the coupling section between the gate electrode of the transfer transistor and the control signal line illustrated in FIG. 58 as viewed in the arrow Y direction.

FIG. 61 is a side configuration diagram of the coupling section between the gate electrode of the transfer transistor and the control signal line illustrated in FIG. 58 as viewed in the arrow X direction.

FIG. 62 is a perspective view illustrating a three-dimensional configuration of a coupling section between a gate electrode of a transfer transistor and a control signal line of a solid-state imaging device according to a third modification example of the eleventh embodiment.

FIG. 63 is a planar configuration diagram of the coupling section between the gate electrode of the transfer transistor and the control signal line illustrated in FIG. 62 as viewed from the arrow Z direction.

FIG. 64 is a side configuration diagram of the coupling section between the gate electrode of the transfer transistor and the control signal line illustrated in FIG. 62 as viewed in the arrow Y direction.

FIG. 65 is a side configuration diagram of the coupling section between the gate electrode of the transfer transistor and the control signal line illustrated in FIG. 62 as viewed in the arrow X direction.

FIG. 66 is a perspective view illustrating a three-dimensional configuration of a coupling section between a gate electrode of a transfer transistor and a control signal line of a solid-state imaging device according to a fourth modification example of the eleventh embodiment.

FIG. 67 is a planar configuration diagram of the coupling section between the gate electrode of the transfer transistor and the control signal line illustrated in FIG. 66 as viewed from the arrow Z direction.

FIG. 68 is a side configuration diagram of the coupling section between the gate electrode of the transfer transistor and the control signal line illustrated in FIG. 66 as viewed in the arrow Y direction.

FIG. 69 is a side configuration diagram of the coupling section between the gate electrode of the transfer transistor and the control signal line illustrated in FIG. 66 as viewed in the arrow X direction.

FIG. 70 is a perspective view illustrating a three-dimensional configuration of a coupling section between a gate electrode of a transfer transistor and a control signal line of a solid-state imaging device according to a fifth modification example of the eleventh embodiment.

FIG. 71 is a planar configuration diagram of the coupling section between the gate electrode of the transfer transistor and the control signal line illustrated in FIG. 70 as viewed from the arrow Z direction.

FIG. 72 is a side configuration diagram of the coupling section between the gate electrode of the transfer transistor and the control signal line illustrated in FIG. 70 as viewed in the arrow Y direction.

FIG. 73 is a side configuration diagram of the coupling section between the gate electrode of the transfer transistor and the control signal line illustrated in FIG. 70 as viewed in the arrow X direction.

FIG. 74 is a perspective view illustrating a three-dimensional configuration of a coupling section between a gate electrode of a transfer transistor and a control signal line of a solid-state imaging device according to a sixth modification example of the eleventh embodiment.

FIG. 75 is a planar configuration diagram of the coupling section between the gate electrode of the transfer transistor and the control signal line illustrated in FIG. 74 as viewed from the arrow Z direction.

FIG. 76 is a side configuration diagram of the coupling section between the gate electrode of the transfer transistor and the control signal line illustrated in FIG. 74 as viewed in the arrow Y direction.

FIG. 77 is a side configuration diagram of the coupling section between the gate electrode of the transfer transistor and the control signal line illustrated in FIG. 74 as viewed in the arrow X direction.

FIG. 78 is a perspective view illustrating a three-dimensional configuration of a coupling section between a gate electrode of a transfer transistor and a control signal line of a solid-state imaging device according to a seventh modification example of the eleventh embodiment.

FIG. 79 is a planar configuration diagram of the coupling section between the gate electrode of the transfer transistor and the control signal line illustrated in FIG. 78 as viewed from the arrow Z direction.

FIG. 80 is a side configuration diagram of the coupling section between the gate electrode of the transfer transistor and the control signal line illustrated in FIG. 78 as viewed in the arrow Y direction.

FIG. 81 is a side configuration diagram of the coupling section between the gate electrode of the transfer transistor and the control signal line illustrated in FIG. 78 as viewed in the arrow X direction.

FIG. 82 is a perspective view illustrating a three-dimensional configuration of a coupling section between a gate electrode of a transfer transistor and a control signal line of a solid-state imaging device according to an eighth modification example of the eleventh embodiment.

FIG. 83 is a planar configuration diagram of the coupling section between the gate electrode of the transfer transistor and the control signal line illustrated in FIG. 82 as viewed from the arrow Z direction.

FIG. 84 is a side configuration diagram of the coupling section between the gate electrode of the transfer transistor and the control signal line illustrated in FIG. 82 as viewed in the arrow Y direction.

FIG. 85 is a side configuration diagram of the coupling section between the gate electrode of the transfer transistor and the control signal line illustrated in FIG. 82 as viewed in the arrow X direction.

FIG. 86 is a perspective view illustrating a three-dimensional configuration of a coupling section between a gate electrode of a transfer transistor and a control signal line of a solid-state imaging device according to a ninth modification example of the eleventh embodiment.

FIG. 87 is a planar configuration diagram of the coupling section between the gate electrode of the transfer transistor and the control signal line illustrated in FIG. 86 as viewed from the arrow Z direction.

FIG. 88 is a side configuration diagram of the coupling section between the gate electrode of the transfer transistor and the control signal line illustrated in FIG. 86 as viewed in the arrow Y direction.

FIG. 89 is a side configuration diagram of the coupling section between the gate electrode of the transfer transistor and the control signal line illustrated in FIG. 86 as viewed in the arrow X direction.

FIG. 90 is a block diagram depicting an example of schematic configuration of a vehicle control system.

FIG. 91 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. It is to be noted that the description is given in the following order.

### 1. First Embodiment

A first embodiment describes an example in which the present technology is applied to a solid-state imaging device. The first embodiment gives a detailed description of a circuit configuration, a planar configuration, and a vertical cross-sectional configuration of a pixel and a pixel circuit of the solid-state imaging device and a method of manufacturing the solid-state imaging device.

### 2. Second Embodiment

A second embodiment describes an example in which a configuration of a pixel isolation region is changed in the solid-state imaging device according to the first embodiment. The second embodiment mainly describes a method of manufacturing the solid-state imaging device.

### 3. Third Embodiment

A third embodiment describes an example in which an arrangement of a transfer transistor, a control signal line, and a floating diffusion region is changed in the solid-state imaging device according to the first embodiment.

### 4. Fourth Embodiment

A fourth embodiment describes a first example in which a shape of the transfer transistor is changed in the solid-state imaging device according to the third embodiment.

### 5. Fifth Embodiment

A fifth embodiment describes a second example in which the shape of the transfer transistor is changed in the solid-state imaging device according to the third embodiment.

### 6. Sixth Embodiment

A sixth embodiment describes a third example in which the shape of the transfer transistor is changed in the solid-state imaging device according to the third embodiment.

### 7. Seventh Embodiment

A seventh embodiment describes a fourth example in which the shape of the transfer transistor is changed in the solid-state imaging device according to the third embodiment.

### 8. Eighth Embodiment

An eighth embodiment describes a first application example of the solid-state imaging device according to the first embodiment. The first application example is an example in which one pixel circuit is shared by four pixels in a solid-state imaging device having a single-layer pixel structure.

### 9. Ninth Embodiment

A ninth embodiment describes a second application example of the solid-state imaging device according to the first embodiment. The second application example is an example in which two pixels are shared in a solid-state imaging device having a single-layer pixel structure.

### 10. Tenth Embodiment

A tenth embodiment describes a third application example of the solid-state imaging device according to the first embodiment. The third application example is an example in which one pixel circuit is shared by four pixels in a solid-state imaging device having a two-layer pixel structure.

### 11. Eleventh Embodiment

An eleventh embodiment describes a fifth example in which the shape of the transfer transistor is changed in the solid-state imaging device according to the third embodiment. Described here are first to ninth modification examples in which the shape of the transfer transistor is further changed.

### 12. Application Example to Mobile Body

Described is an example in which the present technology is applied to a vehicle control system as an example of a mobile body control system.

### 13. Other Embodiments

### 1. First Embodiment

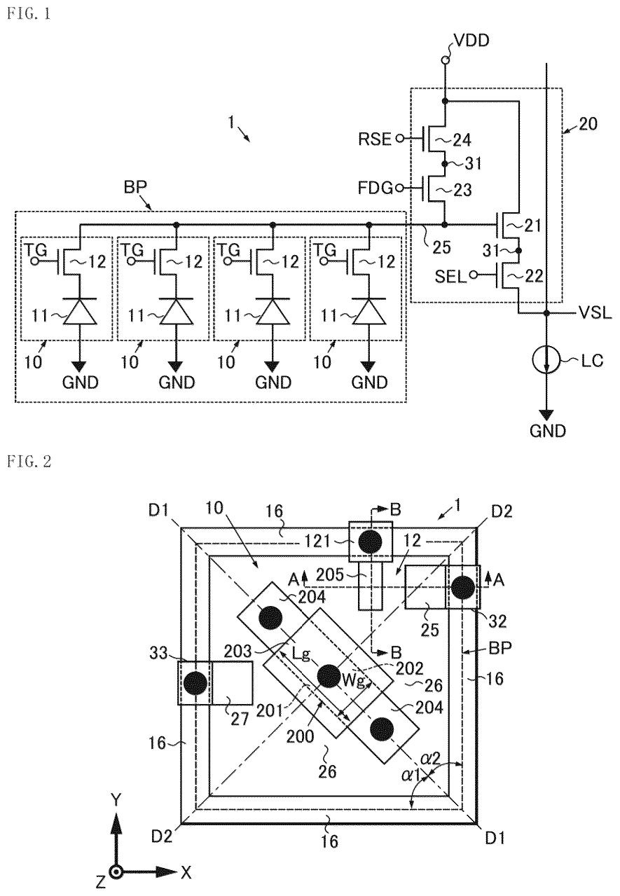

With reference to FIGS. 1 to 17, a description will be given of a solid-state imaging device 1 according to a first embodiment of the present disclosure and a method of manufacturing the solid-state imaging device 1.

Here, in the drawings, an arrow X direction illustrated appropriately represents one plane direction of the solid-state imaging device 1 placed on a plane, for convenience. An arrow Y direction represents another one plane direction orthogonal to the arrow X direction. In addition, an arrow Z direction represents an upward direction orthogonal to the arrow X direction and the arrow Y direction. In other words, the arrow X direction, the arrow Y direction, and the arrow Z direction exactly correspond to an X axis direction, a Y axis direction, and a Z axis direction, respectively, of a three-dimensional coordinate system.

It is to be noted that these directions are each illustrated to help understand the description, and not intended to limit directions of the present technology.

### [Configuration of Solid-State Imaging Device 1]

### (1) Circuit Configuration of Pixels 10 and Pixel Circuit 20 of Solid-State Imaging Device 1

FIG. 1 illustrates an example of a circuit configuration of pixels 10 and a pixel circuit 20 included in the solid-state imaging device 1.

One pixel 10 includes a series circuit of a photoelectric conversion element (photodiode) 11 and a transfer transistor 12. Here, four pixels 10 are configured as a unit pixel BP. Note that the unit pixel BP may include one, two, three, or five or more pixels 10.

The photoelectric conversion element 11 converts light that is incident from outside the solid-state imaging device 1 into electric charge (an electric signal).

The transfer transistor 12 includes a gate electrode and a pair of main electrodes. Of the pair of main electrodes, one main electrode is electrically coupled to the photoelectric conversion element 11. The other main electrode is electrically coupled to a floating diffusion region (hereinafter, simply referred to as “FD region”) 25, and is coupled to the pixel circuit 20 through the FD region 25. The gate electrode is coupled to a control signal line (horizontal signal line) unillustrated here. The gate electrode receives a control signal TG from the control signal line. The control signal TG controls conducting or non-conducting operation of the transfer transistor 12, to control transfer of the electric charge from the photoelectric conversion element 11 to the FD region 25 through the transfer transistor 12.

Here, the pixel circuit 20 is provided for each unit pixel BP. In other words, one pixel circuit 20 is provided for four pixels 10. The pixel circuit 20 performs signal processing on the electric charge converted from light in the pixel 10.

In the first embodiment, the pixel circuit 20 includes four transistors of a first transistor to a fourth transistor.

Here, the first transistor is an amplification transistor 21 having a gate electrode and a pair of main electrodes. The second transistor is a selection transistor 22 having a gate electrode and a pair of main electrodes. The third transistor is a floating diffusion conversion gain switching transistor (hereinafter, simply referred to as “FD conversion gain switching transistor”) 23 having a gate electrode and a pair of main electrodes. Further, the fourth transistor is a reset transistor 24 having a gate electrode and a pair of main electrodes.

The gate electrode of the amplification transistor 21 is coupled to the FD region 25. One main electrode of the amplification transistor 21 is coupled to a power supply voltage terminal VDD, the other main electrode is coupled to one main electrode of the selection transistor 22.

The gate electrode of the selection transistor 22 is coupled to a selection signal line SEL. The other main electrode of the selection transistor 22 is coupled to a vertical signal line VSL and a current source load LC. The current source load LC is coupled to a reference voltage terminal GND.

The gate electrode of the FD conversion gain switching transistor 23 is coupled to a floating diffusion control signal line FDG. One main electrode of the FD conversion gain switching transistor 23 is coupled to the FD region 25, and the other main electrode is coupled to one main electrode of the reset transistor 24.

The gate electrode of the reset transistor 24 is coupled to a reset signal line RST. The other main electrode of the reset transistor 24 is coupled to the power supply voltage terminal VDD.

In the solid-state imaging device 1, the pixel circuit 20 is further coupled to an unillustrated image processing circuit. The image processing circuit includes, for example, an analog-to-digital converter (ADC) and a digital signal processor (DSP).

The electric charge converted from light by the pixel 10 is an analog signal. The analog signal is amplified in the pixel circuit 20. The ADC converts the analog signal outputted from the pixel circuit 20 into a digital signal. The DSP performs functional processing on the digital signal. In other words, the image processing circuit performs signal processing for image generation.

### (2) Basic Layout Configuration of Pixel 10 and Transistor 200 Included in Pixel Circuit 20

FIG. 2 illustrates an example of a basic configuration of the pixel 10 and a transistor 200 included in the pixel circuit 20.

As viewed from the arrow Z direction (hereinafter, simply referred to as “in plan view”), one pixel 10 and the transistor 200 included in the pixel circuit 20 are provided in a region surrounded by a pixel isolation region 16. The pixel isolation region 16 electrically and optically isolates the pixel 10 from other regions.

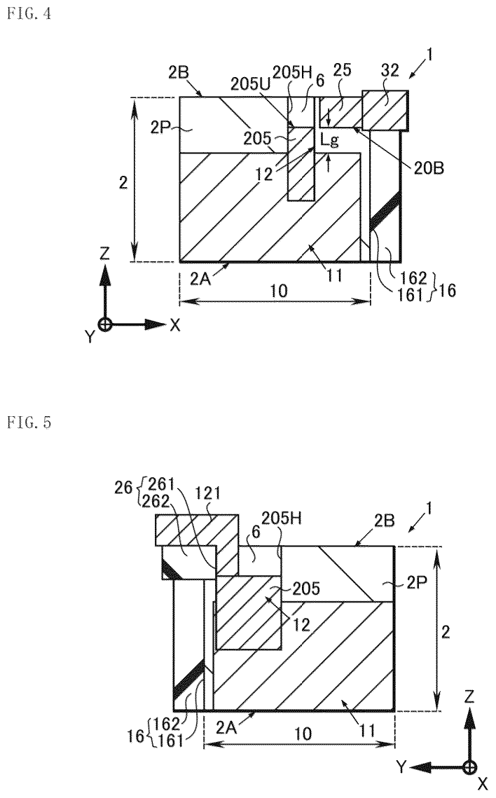

Here, the plan view is used to mean as viewed from a “second surface 2B (see FIG. 4)” side according to the present technology. A side opposite to the arrow Z direction is configured as a light incident surface. The light incident surface is a “first surface 2A (see FIG. 4)” according to the present technology. The photoelectric conversion element 11 included in the pixel 10 is provided on the light incident surface side.

The pixel isolation region 16 extends in the arrow X direction with a constant width dimension, and multiple pixel isolation regions 16 are arranged in the arrow Y direction with a constant separation dimension. Similarly, the pixel isolation region 16 extends in the arrow Y direction with a constant width dimension, and multiple pixel isolation regions 16 are arranged in the arrow X direction with a constant separation dimension. In other words, the pixel isolation region 16 is provided in a grid shape in plan view, and the pixel 10 and the transistor 200 are provided in a region defined by the pixel isolation region 16.

Here, the arrow X direction is a “first direction” according to the present technology. In addition, the arrow Y direction is a “second direction” according to the present technology, which intersects the first direction.

Although not particularly limited, in the first embodiment, the pixel 10 and the transistor 200 are provided in a region defined as a square shape by the pixel isolation region 16 in plan view. Here, one pixel 10 is provided in one region defined by the pixel isolation region 16. Further, one transistor 200 included in the pixel circuit 20 is provided in one region defined by the pixel isolation region 16.

Note that a vertical cross-sectional structure of the pixel isolation region 16 and the like will be described later.

The transistor 200 is the first transistor, the second transistor, the third transistor, or the fourth transistor. That is, the transistor 200 is any of the amplification transistor 21, the selection transistor 22, the FD conversion gain switching transistor 23, and the reset transistor 24.

The transistor 200 is surrounded by an element isolation region 26 and is at least electrically isolated from other regions. The transistor 200 includes a channel formation region 201, a gate insulating film 202, a gate electrode 203, and a pair of main electrodes 204. The main electrode 204 includes an n-type semiconductor region as a first conductivity type, and is used as a source electrode or a drain electrode.

Here, the transistor 200 is an n-channel insulated gate field-effect transistor (IGFET: Insulated Gate Field Effect Transistor). The IGFET includes a metal-oxide-semiconductor field-effect transistor (MOSFET: Metal Oxide Semiconductor Field Effect Transistor) and a metal-insulator-semiconductor field-effect transistor (MISFET: Metal Insulator Semiconductor Field Effect Transistor).

In the first embodiment, in a region corresponding to the pixel 10, the transistor 200 is disposed in a diagonal direction with respect to the extending direction of the pixel isolation region 16. That is, the transistor 200 is disposed in the diagonal direction with respect to the arrow X direction or the arrow Y direction.

Specifically, the transistor 200 is disposed to have a gate length Lg direction matching a diagonal line D1-D1 from the upper left side to the lower right side illustrated as an imaginary line, in the region (the region with the square shape in plan view) defined by the pixel isolation region 16. The gate length Lg is an effective length of the gate electrode 203 between the pair of main electrodes 204. In addition, a gate width Wg is a length in a direction that is orthogonal to the gate length Lg direction and matches a diagonal line D2-D2 from the lower left side to the upper right side illustrated as an imaginary line.

Here, a minimum angle α1 formed by the pixel isolation region 16 extending in the arrow X direction and the diagonal line D1-D1 is 45 degrees. The maximum angle is 135 degrees. A minimum angle α2 formed by the pixel isolation region 16 extending in the arrow Y direction and the diagonal line D1-D1 is 45 degrees, as a matter of course. Setting the angle α1 to 45 degrees makes it possible to maximize the gate length Lg dimension and the gate width Wg dimension in the transistor 200.

Note that the angle α1 may be appropriately set within angles of greater than or equal to 30 degrees and less than 90 degrees. To put it another way, when the transistor 200 is disposed diagonally, it is possible to increase the gate length Lg and the gate width Wg of the transistor 200 as compared with when the transistor 200 is not disposed diagonally.

In contrast, in the region defined by the pixel isolation region 16, the transfer transistor 12 and the FD region 25 are provided in a region along the diagonal line D2-D2 on the upper right side with respect to the transistor 200.

The transfer transistor 12 is provided at a position along the pixel isolation region 16 extending in the arrow X direction, in the vicinity of an intersection between the pixel isolation region 16 extending in the arrow X direction and the pixel isolation region 16 extending in the arrow Y direction. The transfer transistor 12 is configured as a vertical transistor having a vertical gate electrode (gate electrode) 205 extending in the arrow Z direction as the gate length Lg direction. Here, the transfer transistor 12 includes an n-channel conductivity type IGFET.

The FD region 25 is provided at a position along the pixel isolation region 16 extending in the arrow Y direction, in the vicinity of the intersection between the pixel isolation region 16 extending in the arrow X direction and the pixel isolation region 16 extending in the arrow Y direction. The FD region 25 includes an n-type semiconductor region. The FD region 25 is disposed with the element isolation region 26 interposed between the FD region 25 and the transistor 200.

In addition, in the region defined by the pixel isolation region 16, a base body coupling section 27 is provided in a region along the diagonal line D2-D2 on the lower left side with respect to the transistor 200. The base body coupling section 27 is provided at an intermediate portion of the pixel isolation region 16 extending in the arrow Y direction. The base body coupling section 27 includes a p-type semiconductor region as a second conductivity type. The base body coupling section 27 is a well contact region and is coupled to the reference voltage terminal GND. In other words, the base body coupling section 27 supplies a reference voltage to a p-type well region.

Note that a portion indicated by a black circle in FIG. 2 is a region (contact region) coupled to a wiring 7 (see FIG. 17) provided in an upper layer of the transistor 200 on a side opposite to the photoelectric conversion element 11. Used as the wiring 7 is, for example, a copper (Cu) wiring.

### (3) Layout Configuration of Pixels 10

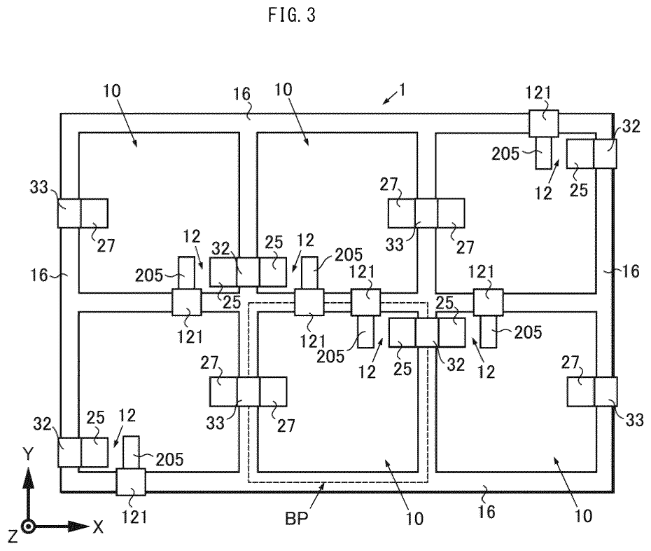

FIG. 3 illustrates an example of a layout configuration in which multiple pixels 10 are arranged.

Multiple pixels 10 are arranged at regular intervals in the arrow X direction, and multiple pixels 10 are arranged at regular intervals in the arrow Y direction. In other words, the multiple pixels 10 are arranged in a matrix in plan view.

Between the multiple pixels 10 arranged in the arrow X direction, the pixel isolation region 16 having the arrow X direction as a width direction extends in the arrow Y direction. Between the multiple pixels 10 arranged in the arrow Y direction, the pixel isolation region 16 having the arrow Y direction as a width direction extends in the arrow X direction.

### (4) Basic Layout Configuration of Shared Coupling Sections 32 and 33

A shared coupling (Shared Contact or Side Contact) section 32 and a shared coupling section 33 are provided between the multiple pixels 10.

As illustrated in FIGS. 2 and 3, here, the shared coupling section 32 is provided between the FD region 25 of the pixel 10 and the FD region 25 of the other pixel 10 adjacent in the arrow X direction. Specifically, the shared coupling section 32 is formed across the FD regions 25 of a total of two pixels 10 adjacent to each other in the arrow X direction, and is electrically and directly coupled to the total of two FD regions 25.

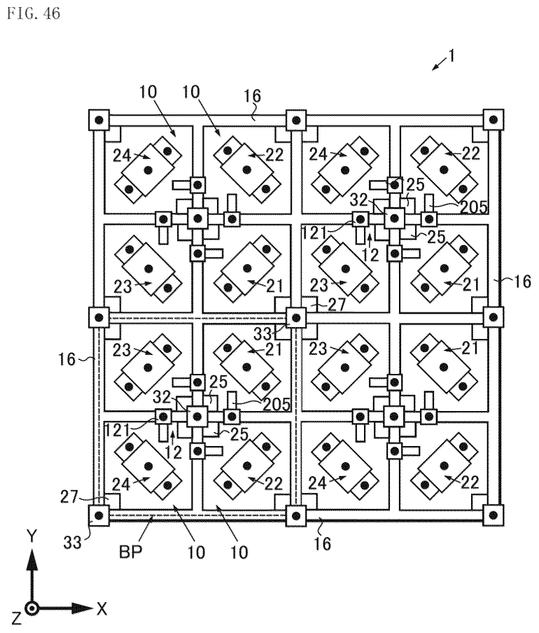

Alternatively, the shared coupling section 32 may be formed across the FD regions 25 of a total of four pixels 10 adjacent to each other in the arrow X direction and the arrow Y direction, and may be electrically coupled to the total of four FD regions 25 (see FIG. 46). In other words, the shared coupling section 32 is formed across the FD regions 25 of the multiple pixels 10.

Here, the shared coupling section 33 is provided between the base body coupling section 27 of the pixel 10 and the base body coupling section 27 of the other pixel 10 adjacent in the arrow X direction. As with the shared coupling section 32, the shared coupling section 33 is formed across the base body coupling sections 27 of a total of two pixels 10 adjacent to each other in the arrow X direction, and is electrically and directly coupled to the total of two base body coupling sections 27.

Alternatively, the shared coupling section 33 may be formed across the base body coupling sections 27 of a total of four pixels 10 adjacent to each other in the arrow X direction and the arrow Y direction, and may be electrically coupled to the total of four base body coupling sections 27 (see FIG. 46).

### (5) Vertical Cross-Sectional Configuration of Pixel 10

FIG. 4 illustrates an example of a specific cross-sectional configuration of the pixel 10 illustrated in FIG. 2 taken along a line A-A. FIG. 5 illustrates an example of a specific cross-sectional configuration of the pixel 10 illustrated in FIG. 2 taken along a line B-B.

As illustrated in FIGS. 4 and 5, the photoelectric conversion element 11 of the pixel 10 is provided on the first surface 2A side of the base body 2. Here, for example, a semiconductor substrate is used as the base body 2. More specifically, a single-crystal silicon substrate having a p-type semiconductor region (or p-type well region) 2P is used. The photoelectric conversion element 11 is formed at a pn junction between the p-type semiconductor region 2P and an n-type semiconductor region not denoted by a reference numeral.

The pixel isolation region 16 surrounding the pixel 10 includes a first groove 161 and a first embedded member 162.

The first groove 161 is formed as a deep groove penetrating the base body 2 in a thickness direction, from an upper surface on the second surface 2B side to a lower surface on the first surface 2A side of the base body 2.

The first embedded member 162 is embedded in the first groove 161. Here, the first embedded member 162 includes an insulator provided along an inner wall of the first groove 161 and an embedded member embedded in the first groove 161 with the insulator interposed therebetween. Used as the insulator is, for example, a silicon oxide film, a silicon nitride film, or the like. Used as the embedded member is, for example, a polycrystalline silicon film.

In other words, the pixel isolation region 16 is configured by a trench isolation structure.

In addition, although not illustrated or described in detail here, a pinning region is provided between the photoelectric conversion element 11 and the pixel isolation region 16 inside the base body 2, in a region corresponding to the photoelectric conversion element 11.

Further, as illustrated in FIG. 5, the pixel isolation region 16 includes the element isolation region 26. As described above, the element isolation region 26 provides electrical isolation, for example, between the transistor 200 and the FD region 25, between the transistor 200 and the base body coupling section 27, and the like. The element isolation region 26 includes a second groove 261 and a second embedded member 262.

The second groove 261 is a groove formed in the thickness direction from the upper surface of the base body 2 toward the lower surface side. The second groove 261 is a groove to an extent that does not reach the photoelectric conversion element 11, and the second groove 261 has a depth shallower than the depth of the first groove 161. In addition, here, a groove width of the second groove 261 is wider than a groove width of the first groove 161.

The second embedded member 262 is embedded in the second groove 261. The second embedded member 262 includes, for example, an insulating material similar to the insulator of the first embedded member 162.

The element isolation region 26 is configured by a trench isolation structure.

Here, as illustrated in FIG. 4, the shared coupling section 32 is provided in a region resulting from removing a portion of the pixel isolation region 16 on the second surface 2B side. Specifically, in a region resulting from removing a portion of the element isolation region 26 included in the pixel isolation region 16, the shared coupling section 32 is provided across the pixel isolation region 16.

The shared coupling section 32 includes a gate electrode material, specifically, for example, a polycrystalline silicon film. The polycrystalline silicon film includes an n-type impurity introduced therein to reduce a resistance value.

In addition, the shared coupling section 33 basically has the same configuration as the shared coupling section 32, but the polycrystalline silicon film includes a p-type impurity introduced therein.

As illustrated in FIGS. 4 and 5, the transfer transistor 12 includes the vertical gate electrode 205. In the first embodiment, in plan view, the vertical gate electrode 205 is formed in a rectangular shape of a rectangle having a length in the arrow Y direction longer than a length in the arrow X direction. The vertical gate electrode 205 extends in the thickness direction of the base body 2 as the gate length Lg direction. In other words, the vertical gate electrode 205 is formed in a rectangular parallelepiped shape.

Note that a corner portion of the vertical gate electrode 205 may be formed in a chamfered shape or a curved shape (R shape). Providing such a shape makes it possible to relieve electric field concentration at the corner portion.

One end of the vertical gate electrode 205 on the first surface 2A side is formed to reach the n-type semiconductor region of the photoelectric conversion element 11. The n-type semiconductor region of the photoelectric conversion element 11 is one of the main electrodes of the transfer transistor 12.

In contrast, the other end of the vertical gate electrode 205 on the second surface 2B side is coupled to the FD region 25. The FD region 25 is the other main electrode of the transfer transistor 12. Here, the other end of the vertical gate electrode 205 is provided on the first surface 2A side with respect to the second surface 2B of the base body 2. Specifically, a third surface (upper surface) 205U of the vertical gate electrode 205 on the second surface 2B side, is formed at the same position or a position on the first surface 2A side, with respect to a fourth surface (lower surface) 25B of the FD region 25 on the first surface 2A side.

Here, the FD region 25 is formed in a rectangular shape in plan view. Further, because the vertical gate electrode 205 is formed in a rectangular shape as described above, the vertical gate electrode 205 is provided along a side surface corresponding to one side of the FD region 25.

The other end of the vertical gate electrode 205 is formed in a cross-sectional shape dug down with respect to the second surface 2B of the base body 2. An interlayer insulating film 6 as an insulator is embedded in the dug-down part. The interlayer insulating film 6, which will be described later, is formed between the transistor 200 and the wiring 7 (see FIG. 17) provided in the upper layer of the transistor 200, and a portion of the interlayer insulating film 6 is embedded in the dug-down part. The interlayer insulating film 6 includes, for example, a silicon oxide film.

A gate insulating film of the transfer transistor 12 is not illustrated or denoted by a reference numeral, but is provided between the vertical gate electrode 205 and the p-type semiconductor region 2P. A part of the p-type semiconductor region 2P that contacts the gate insulating film is used as a channel formation region.

Further, as illustrated in FIGS. 2 and 5, to the other end of the vertical gate electrode 205 of the transfer transistor 12, a coupling section 121 of the control signal line is electrically coupled to electrically couple the control signal line (the “wiring 7” illustrated in FIG. 17) and the vertical gate electrode 205 to each other. The coupling section 121 receives the control signal TG from the control signal line to the transfer transistor 12.

### (6) Specific Configuration of Coupling Section 121

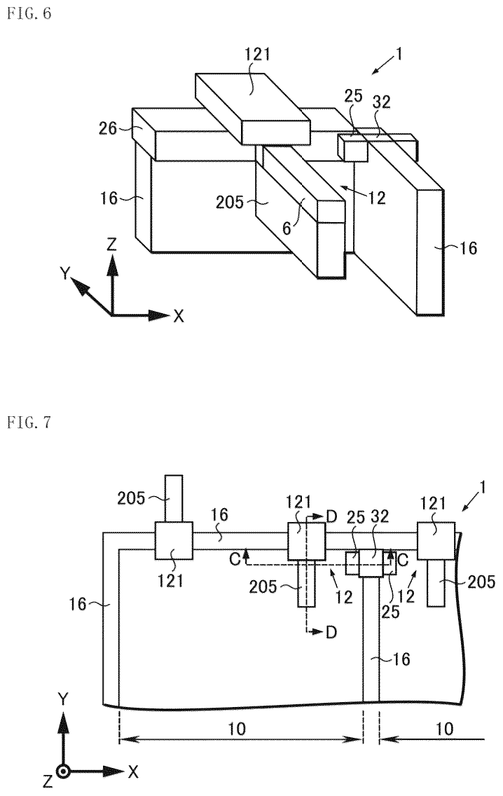

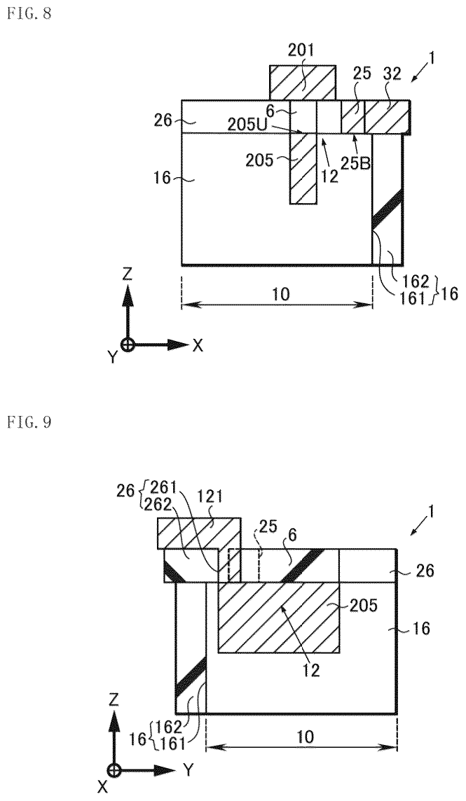

FIG. 6 illustrates an example of a three-dimensional configuration of the pixel 10, the transfer transistor 12, the coupling section 121, and the FD region 25 illustrated in FIGS. 4 and 5. FIG. 7 illustrates an example of a planar configuration of the pixel 10 and the like illustrated in FIG. 6 as viewed from the arrow Z direction. FIG. 8 illustrates an example of a vertical cross-sectional configuration of the pixel 10 and the like as viewed in the arrow Y direction taken along a line C-C illustrated in FIG. 7. FIG. 9 illustrates an example of a vertical cross-sectional configuration of the pixel 10 and the like as viewed in the arrow X direction taken along a line D-D illustrated in FIG. 7.

As illustrated in FIGS. 6 to 9, the coupling section 121 is provided at a position overlapping the pixel isolation region 16 on the second surface 2B side of the base body 2. Specifically, in the first embodiment, the coupling section 121 and the control signal line (wiring 7) coupled thereto are provided on the pixel isolation region 16 to overlap the pixel isolation region 16 extending in the arrow X direction, at a position close to the vertical gate electrode 205 of the transfer transistor 12. Hereinafter, the coupling section 121 will be mainly described, and a description of the control signal line will be omitted.

Here, a width dimension of the coupling section 121 in the arrow Y direction is formed greater, at least on the transfer transistor 12 side, than the width dimension of the pixel isolation region 16 extending in the arrow X direction. In other words, in plan view, a portion of the coupling section 121 extends to a position overlapping the vertical gate electrode 205. At the position to which the coupling section 121 extends, the coupling section 121 is electrically coupled to the vertical gate electrode 205. Therefore, the coupling section 121 is electrically coupled to the vertical gate electrode 205, substantially without contacting a surface of the p-type semiconductor region 2P of the base body 2.

Here, the FD region 25 is provided at a position in the vicinity of the pixel isolation region 16 extending in the arrow Y direction, and is coupled to the other FD region 25 through the shared coupling section 32 provided across the pixel isolation region 16 extending in the arrow Y direction.

In addition, a corner portion of the FD region 25 may be formed in a chamfered shape or a curved shape, as with the corner portion of the vertical gate electrode 205.

### [Method of Manufacturing Solid-State Imaging Device 1]

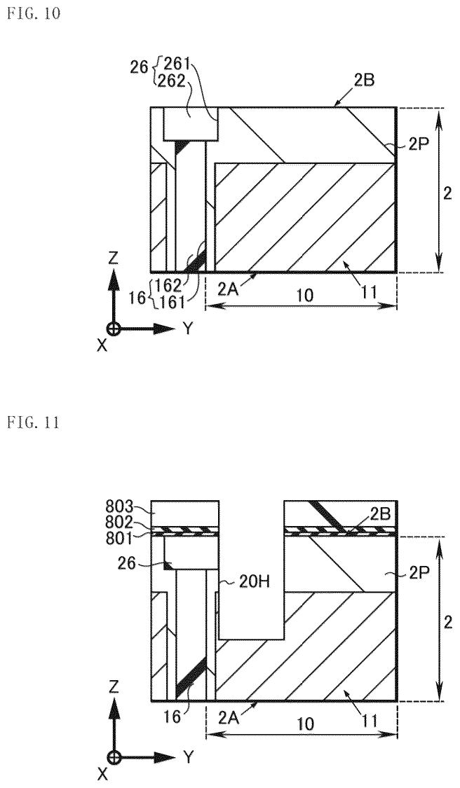

FIGS. 10 to 17 illustrate respective steps of an example of a method of manufacturing the solid-state imaging device 1. Here, a detailed description will be given of a method of manufacturing the pixel isolation region 16, the element isolation region 26, the transfer transistor 12, and the coupling section 121.

In a region between the pixels 10, the pixel isolation region 16 is formed in the base body 2 (see FIG. 10). Subsequently, as illustrated in FIG. 10, the element isolation region 26 is formed in the region between the pixels 10 and a region between elements.

The pixel isolation region 16 is formed by forming the first groove 161 and embedding the first embedded member 162 in the first groove 161. The first groove 161 is formed by anisotropic etching such as reactive ion etching (RIE: Reactive Ion Etching). The first embedded member 162 is formed using a polycrystalline silicon film or the like by, for example, a chemical vapor deposition (CVD: Chemical Vaper Deposition) method. The element isolation region 26 is formed by forming the second groove 261 and embedding the second embedded member in the second groove 261. The second groove 261 is formed by anisotropic etching, as with the first groove 161. The second embedded member 262 is formed using a silicon oxide film or the like by a CVD method.

A mask 801, a mask 802, and a mask 803 are sequentially formed on the second surface 2B of the base body 2 (see FIG. 11). For example, a thermal silicon oxide film is used as the mask 801. Used as the mask 802 is, for example, a silicon nitride film that allows an etching selection ratio to be ensured with respect to the mask 801. Used as the mask 803 is, for example, a resist film formed by a photolithography technique.

As illustrated in FIG. 11, in a formation region of the transfer transistor 12, a groove 205H dug down from the second surface 2B of the base body 2 to the first surface 2A side is formed using the masks 801 to 803. The groove 205H is formed by, for example, anisotropic etching.

Thereafter, the mask 803 is removed.

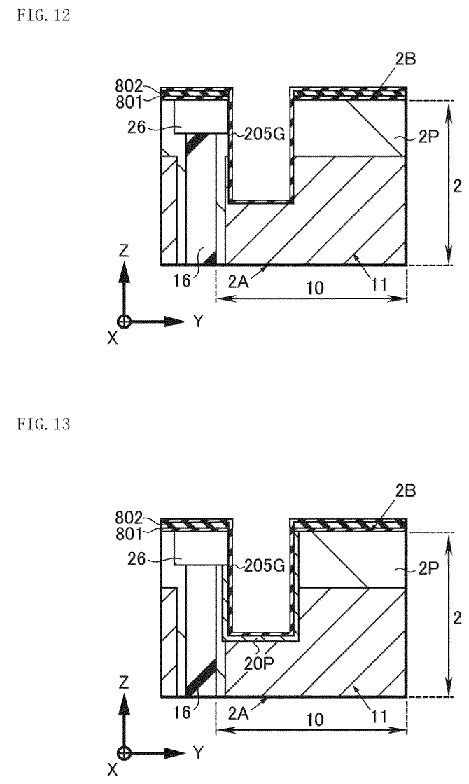

As illustrated in FIG. 12, a gate insulating film 205G is formed on the surface of the base body 2, along an inner wall and a bottom surface of the groove 205H. The gate insulating film 205G is formed using, for example, a silicon oxide film by a CVD method. Subsequently, as illustrated in FIG. 13, a pinning region 20P is formed at a surface portion of the base body 2, along the inner wall and the bottom surface of the groove 205H.

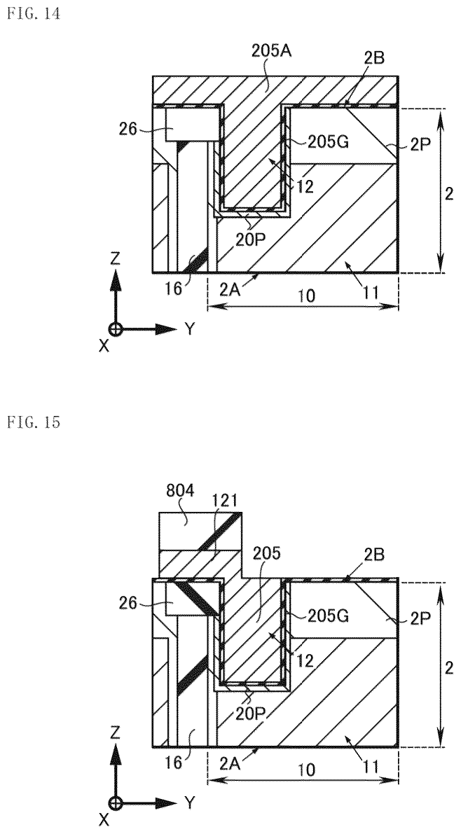

As illustrated in FIG. 14, a gate electrode layer 205A is embedded in the groove 205H and is further formed on the second surface 2B side of the base body 2. The gate electrode layer 205A is formed using, for example, a polycrystalline silicon film by a CVD method. An n-type impurity that reduces the resistance value is introduced into the polycrystalline silicon film during or after the film formation.

As illustrated in FIG. 15, a mask 804 is formed in a formation region of the coupling section 121, and the gate electrode layer 205A is patterned using the mask 804. Used as the mask 804 is, for example, a resist film formed by a photolithography technique.

By the patterning, the coupling section 121 provided to overlap the pixel isolation region 16 is formed from the gate electrode layer 205A. Further, the gate electrode layer 205A is embedded in the groove 205H, and the vertical gate electrode 205 of the transfer transistor 12 is formed from the gate electrode layer 205A.

Thereafter, the mask 804 is removed.

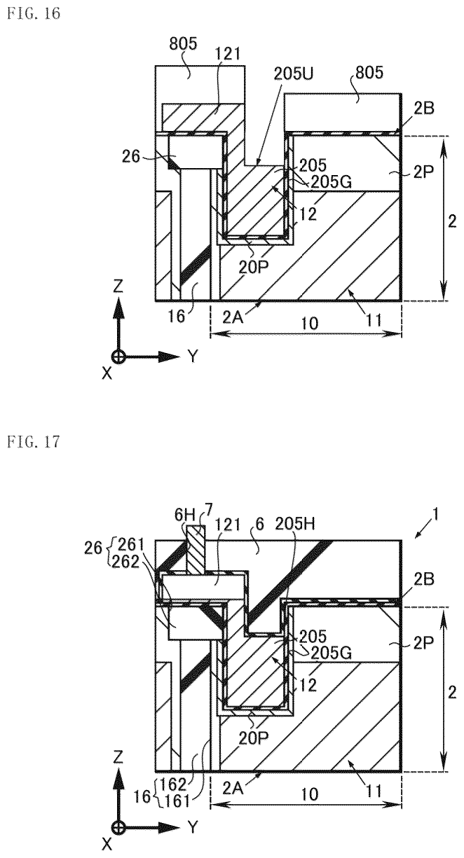

As illustrated in FIG. 16, a mask 805 that is open in a formation region of the vertical gate electrode 205 of the transfer transistor 12 is formed, and the other end of the vertical gate electrode 205 on the second surface 2B side is removed using the mask 805. In other words, a portion of the vertical gate electrode 205 is dug down. The dug-down bottom surface of the vertical gate electrode 205 serves as the third surface 205U. The third surface 205U is formed at the same position or the position on the first surface 2A side, with respect to the fourth surface 25B of the FD region 25 (see FIGS. 8 and 9) to be formed later.

After the unillustrated shared coupling section 32 and shared coupling section 33 (see FIGS. 2 to 4) are formed, the interlayer insulating film 6 is formed (see FIG. 17). The interlayer insulating film 6 is formed using, for example, a silicon oxide film or a silicon nitride film by a CVD method. When the interlayer insulating film 6 is formed, the folded-down part of the vertical gate electrode 205 is embedded by the interlayer insulating film 6.

As illustrated in FIG. 17, a coupling hole 6H is formed in the interlayer insulating film 6, and the wiring 7 that is electrically coupled to the coupling section 121 or the like through the coupling hole 6H is subsequently formed on the interlayer insulating film 6.

When the series of steps ends, the solid-state imaging device 1 according to the first embodiment is completed, and the manufacturing method ends.

### Workings and Effects

As illustrated in FIGS. 1 to 9, the solid-state imaging device 1 according to the first embodiment includes the pixel 10, the transfer transistor 12, and the pixel isolation region 16 (and the element isolation region 26). The pixel 10 is provided on the first surface 2A side as a light incident side of the base body 2, and includes the photoelectric conversion element 11 that converts light into electric charge. The transfer transistor 12 is provided on the second surface 2B side of the base body 2 on the side opposite to the first surface 2A, at a position corresponding to the pixel 10, and has one main electrode 204 electrically coupled to the photoelectric conversion element 11. The pixel isolation region 16 is provided in the thickness direction of the base body 2 to surround the photoelectric conversion element 11 and the transfer transistor 12, and provides electrical and optical isolation.

Here, as illustrated in FIGS. 2, 3, 5 to 7, and 9, the solid-state imaging device 1 further includes the coupling section 121. The coupling section 121 is provided at a position overlapping the pixel isolation region 16 on the second surface 2B side of the base body 2. The control signal line (wiring 7) is electrically coupled to the coupling section 121. Further, the coupling section 121 is electrically coupled to the vertical gate electrode (gate electrode) 205 of the transfer transistor 12.

Therefore, it is possible to effectively suppress or prevent the spread of an electric field from the coupling section 121 to the second surface 2B side of the base body 2. Similarly, it is possible to effectively suppress or prevent the spread of the electric field from the control signal line (wiring 7) to the second surface 2B side of the base body 2. In particular, in a region between the transfer transistor 12 and the FD region 25, it is possible to effectively suppress or prevent the spread of the electric field from the coupling section 121 at the surface portion of the p-type semiconductor region 2P. Thus, it is possible to reduce intensity of the electric field from the coupling section 121, making it possible to improve FD white spot characteristics.

In addition, in the solid-state imaging device 1, as illustrated in FIGS. 2, 3, and 6 to 9, the pixel isolation region 16 includes the pixel isolation region (first pixel isolation region) 16 extending in the arrow X direction and the pixel isolation region (second pixel isolation region) 16 extending in the arrow Y direction intersecting the arrow X direction. Further, in the first embodiment, the coupling section 121 is provided at a position overlapping the pixel isolation region 16 extending in the arrow X direction. In contrast, the FD region 25 is provided at a position that is close to the intersection between the pixel isolation region 16 extending in the arrow X direction and the pixel isolation region 16 extending in the arrow Y direction or the pixel isolation region 16 extending in the arrow Y direction.

Therefore, the coupling section 121 and the FD region 25 are provided to overlap with or close to the pixel isolation regions 16 extending in different directions. The FD region 25 is thus disposed at a position sufficiently separated from the position where the coupling section 121 is disposed. This makes it possible to reduce the intensity of the electric field from the coupling section 121 to the FD region 25.

In addition, in the solid-state imaging device 1, as illustrated in FIGS. 4 and 8, the third surface 205U of the vertical gate electrode 205 of the transfer transistor 12 on the second surface 2B side is formed at the same position as the fourth surface 25B of the FD region 25 on the first surface 2A side, or the position on the first surface 2A side with respect to the fourth surface 25B, in the thickness direction of the base body 2.

Therefore, it is possible to separate a path of the electric charge flowing from the photoelectric conversion element 11 to the FD region 25 through the transfer transistor 12 from the coupling section 121 to the FD region 25 side. The path of the electric charge is thus formed at a position sufficiently separated from the position where the coupling section 121 is disposed, which makes it possible to reduce the intensity of the electric field from the coupling section 121 to the path of the electric charge.

In addition, in the solid-state imaging device 1, as illustrated in FIGS. 4, 5, 6, 8 and 9, the interlayer insulating film 6 as an insulator is provided toward the second surface 2B side, on the third surface 205U of the vertical gate electrode 205 of the transfer transistor 12. The interlayer insulating film 6 is embedded in the groove 205H (see FIGS. 16 and 17) formed from the second surface 2B of the base body 2 to the first surface 2A side, at a position corresponding to the third surface 205U.

Therefore, the path of the electric charge flowing from the photoelectric conversion element 11 to the FD region 25 through the transfer transistor 12 is electrically isolated from the coupling section 121. This makes it possible to reduce the intensity of the electric field from the coupling section 121 to the path of the electric charge.

Further, in the solid-state imaging device 1, as illustrated in FIGS. 16 and 17, the interlayer insulating film 6 provided on the third surface 205U of the vertical gate electrode 205 of the transfer transistor 12 is formed in the same layer and includes the same insulating material as the interlayer insulating film 6 provided on the second surface 2B of the base body 2.

Therefore, the interlayer insulating film 6 is provided on the third surface 205U using the interlayer insulating film 6 that electrically isolates the transistor 200 and the wiring 7 from each other, which makes it possible to easily construct a structure that reduces the intensity of the electric field.

In addition, in the method of manufacturing the solid-state imaging device 1, the step of forming the insulator is eliminated, which makes it possible to reduce the total number of manufacturing steps.

### 2. Second Embodiment

With reference to FIGS. 18 to 25, a description will be given of the solid-state imaging device 1 according to a second embodiment of the present disclosure and a method of manufacturing the solid-state imaging device 1. Note that, in the second embodiment and the subsequent embodiments and modification examples, the same or the substantially same components as the components of the solid-state imaging device 1 according to the first embodiment will be denoted by the same reference numerals, and redundant description will be omitted.

### [Method of Manufacturing Solid-State Imaging Device 1]

FIGS. 18 to 25 illustrate respective steps of an example of a method of manufacturing the solid-state imaging device 1. Here, as with the method of manufacturing the solid-state imaging device 1 according to the first embodiment, a detailed description will be given of a method of manufacturing the pixel isolation region 16, the element isolation region 26, the transfer transistor 12, and the coupling section 121.

As with the method of manufacturing the solid-state imaging device 1 according to the first embodiment (hereinafter, simply referred to as a “first manufacturing method”), in a region between the pixels 10, the pixel isolation region 16 is formed in the base body 2 (see FIG. 18). Subsequently, as illustrated in FIG. 18, the element isolation region 26 is formed in the region between the pixels 10 and a region between elements. Here, the pixel isolation region 16 and the element isolation region 26 provided to overlap the pixel isolation region 16 are formed with the same or substantially the same width dimension. The other components are the same as those of the first manufacturing method.

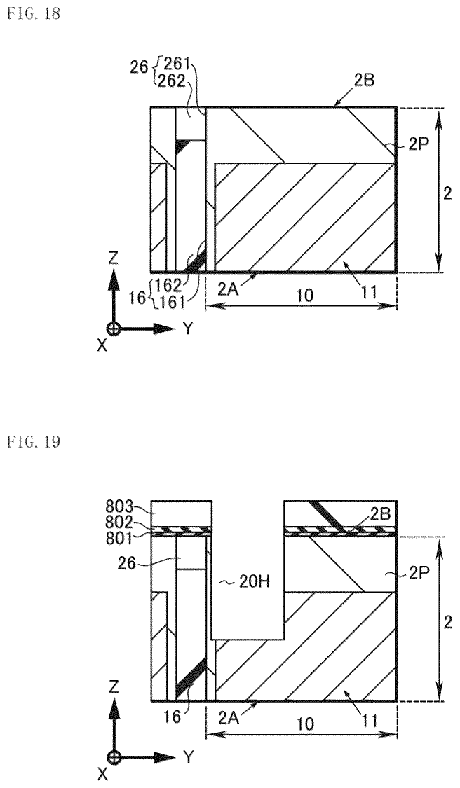

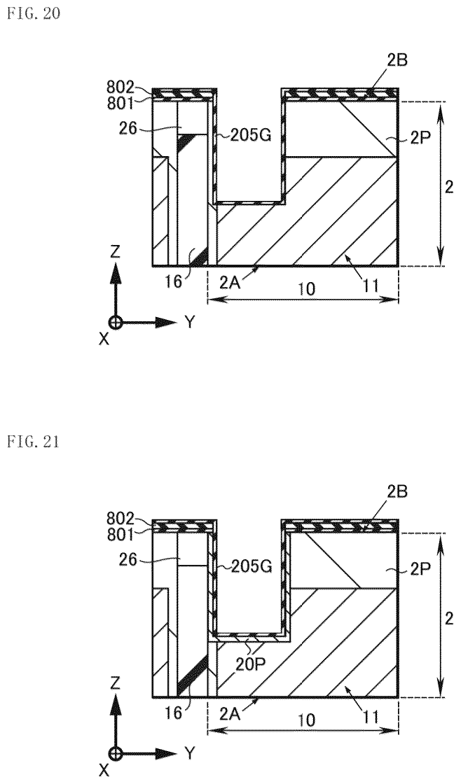

The mask 801, the mask 802, and the mask 803 are sequentially formed on the second surface 2B of the base body 2 (see FIG. 19).

As illustrated in FIG. 19, in a formation region of the transfer transistor 12, the groove 205H dug down from the second surface 2B of the base body 2 to the first surface 2A side is formed using the masks 801 to 803.

Thereafter, the mask 803 is removed.

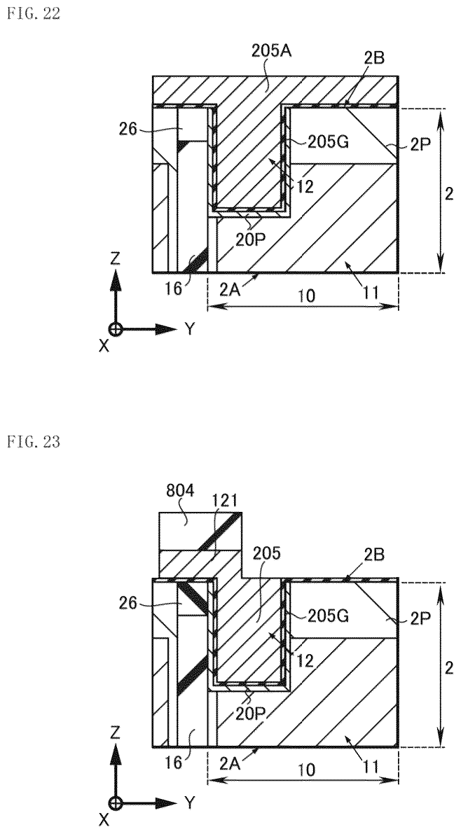

As illustrated in FIG. 20, the gate insulating film 205G is formed on the surface of the base body 2, along the inner wall and the bottom surface of the groove 205H. Subsequently, as illustrated in FIG. 21, the pinning region 20P is formed at the surface portion of the base body 2, along the inner wall and the bottom surface of the groove 205H.

As illustrated in FIG. 22, the gate electrode layer 205A is embedded in the groove 205H and is further formed on the second surface 2B side of the base body 2.

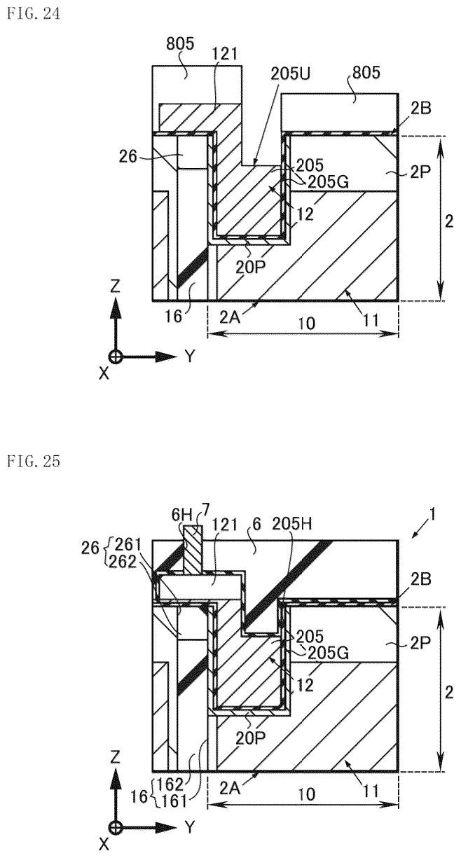

As illustrated in FIG. 23, the mask 804 is formed in a formation region of the coupling section 121, and the gate electrode layer 205A is patterned using the mask 804. By the patterning, the coupling section 121 provided to overlap the pixel isolation region 16 is formed from the gate electrode layer 205A. Further, the gate electrode layer 205A is embedded in the groove 205H, and the vertical gate electrode 205 of the transfer transistor 12 is formed from the gate electrode layer 205A.

Thereafter, the mask 804 is removed.

As illustrated in FIG. 24, the mask 805 that is open in a formation region of the vertical gate electrode 205 of the transfer transistor 12 is formed, and the other end of the vertical gate electrode 205 on the second surface 2B side is removed using the mask 805. In other words, a portion of the vertical gate electrode 205 is dug down. The dug-down bottom surface of the vertical gate electrode 205 serves as the third surface 205U.

As illustrated in FIG. 25, the interlayer insulating film 6, the coupling hole 6H, and the wiring 7 are each formed. The wiring 7 is the control signal line here.

When the series of steps ends, the solid-state imaging device 1 according to the first embodiment is completed, and the manufacturing method ends.

Components other than the above-described components are the same or substantially the same as the components of the solid-state imaging device 1 and the components of the first manufacturing method according to the first embodiment.

### Workings and Effects

The solid-state imaging device 1 and the method of manufacturing the solid-state imaging device 1 according to the second embodiment make it possible to obtain workings and effects similar to the workings and effects obtained by the solid-state imaging device 1 and the first manufacturing method according to the first embodiment.

### 3. Third Embodiment

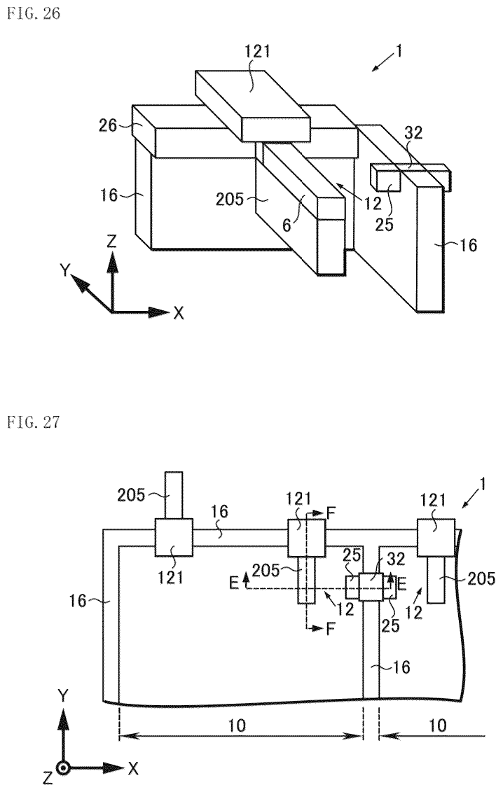

The solid-state imaging device 1 according to a third embodiment of the present disclosure will be described with reference to FIGS. 26 to 29.

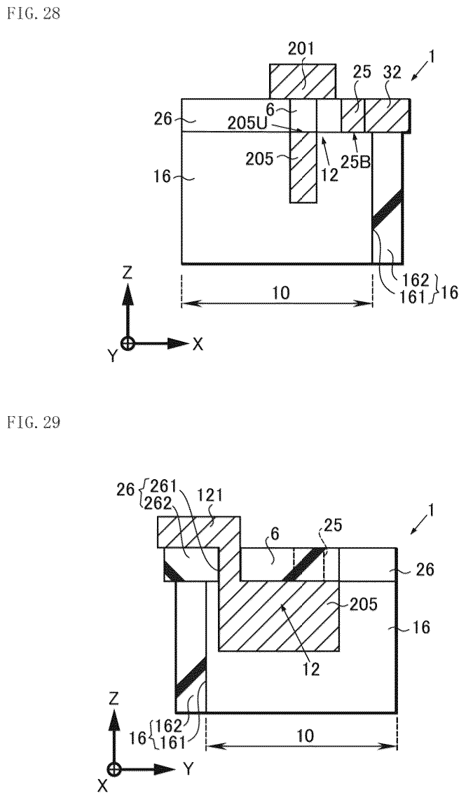

FIG. 26 illustrates an example of a three-dimensional configuration of the pixel 10, the transfer transistor 12, the coupling section 121, and the FD region 25 of the solid-state imaging device 1 according to the third embodiment. FIG. 27 illustrates an example of a planar configuration of the pixel 10 and the like illustrated in FIG. 26 as viewed from the arrow Z direction. FIG. 28 illustrates an example of a vertical cross-sectional configuration of the pixel 10 and the like as viewed in the arrow Y direction taken along a line E-E illustrated in FIG. 27. FIG. 29 illustrates an example of a vertical cross-sectional configuration of the pixel 10 and the like as viewed in the arrow X direction taken along a line F-F illustrated in FIG. 27.

As illustrated in FIGS. 26 to 29, in the solid-state imaging device 1 according to the third embodiment, the coupling section 121 is provided at a position overlapping with the pixel isolation region 16 extending in the arrow X direction on the second surface 2B side of the base body 2, as with the solid-state imaging device 1 according to the first embodiment.

In contrast, the FD region 25 is provided at a position shifted to a side opposite to the arrow Y direction along the pixel isolation region 16 extending in the arrow Y direction. In other words, the FD region 25 is separated from the coupling section 121, as compared with the solid-state imaging device 1 according to the first embodiment.

Components other than the above-described components are the same or substantially the same as the components of the solid-state imaging device 1 according to the first embodiment.

### Workings and Effects

The solid-state imaging device 1 according to the third embodiment makes it possible to obtain workings and effects similar to the workings and effects obtained by the solid-state imaging device 1 according to the first embodiment.

In addition, in the solid-state imaging device 1, the FD region 25 is provided to be separated from the coupling section 121 as illustrated in FIGS. 27 to 29.

Therefore, it is possible to separate a path of the electric charge flowing from the photoelectric conversion element 11 to the FD region 25 through the transfer transistor 12 from the coupling section 121 to the FD region 25 side. The path of the electric charge is thus formed at a position sufficiently separated from the position where the coupling section 121 is disposed, which makes it possible to further reduce the intensity of the electric field from the coupling section 121 to the path of the electric charge.

### 4. Fourth Embodiment

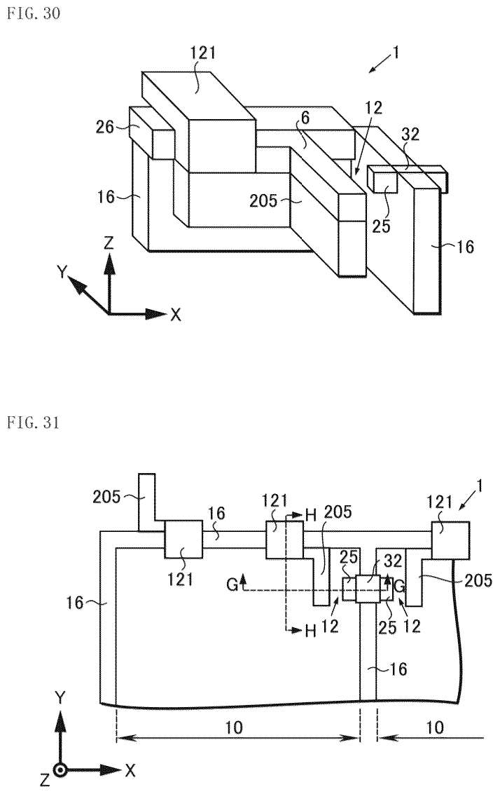

The solid-state imaging device 1 according to a fourth embodiment of the present disclosure will be described with reference to FIGS. 30 to 33.

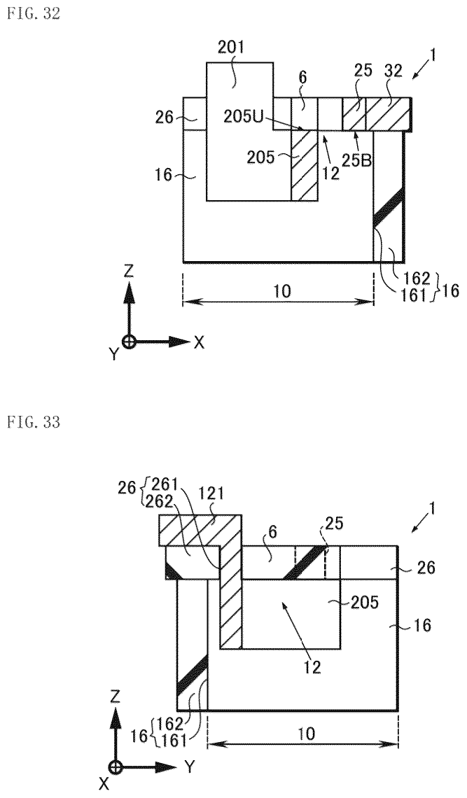

FIG. 30 illustrates an example of a three-dimensional configuration of the pixel 10, the transfer transistor 12, the coupling section 121, and the FD region 25 of the solid-state imaging device 1 according to the fourth embodiment. FIG. 31 illustrates an example of a planar configuration of the pixel 10 and the like illustrated in FIG. 30 as viewed from the arrow Z direction. FIG. 32 illustrates an example of a vertical cross-sectional configuration of the pixel 10 and the like as viewed in the arrow Y direction taken along a line G-G illustrated in FIG. 31. FIG. 33 illustrates an example of a vertical cross-sectional configuration of the pixel 10 and the like as viewed in the arrow X direction taken along a line H-H illustrated in FIG. 31.

As illustrated in FIGS. 30 to 33, in the solid-state imaging device 1 according to the fourth embodiment, the coupling section 121 is provided at a position overlapping with the pixel isolation region 16 extending in the arrow X direction on the second surface 2B side of the base body 2, as with the solid-state imaging device 1 according to the first embodiment.

In contrast, the FD region 25 is provided at a position shifted to the side opposite to the arrow Y direction along the pixel isolation region 16 extending in the arrow Y direction, as with the solid-state imaging device 1 according to the third embodiment. An amount by which the FD region 25 is shifted is further increased.

The vertical gate electrode 205 of the transfer transistor 12 extends in the arrow X direction from a part coupled to the coupling section 121, bends in a direction opposite to the arrow Y direction at the extending end, and further extends to the side opposite to the arrow Y direction. The part of the vertical gate electrode 205 extending to the side opposite to the arrow Y direction is aligned with and opposed to the FD region 25. In other words, the vertical gate electrode 205 is formed in an L-shape in plan view. Consequently, the vertical gate electrode 205 is disposed at a position between the coupling section 121 and the FD region 25.

Components other than the above-described components are the same or substantially the same as the components of the solid-state imaging device 1 according to the third embodiment.

### Workings and Effects

The solid-state imaging device 1 according to the fourth embodiment makes it possible to obtain workings and effects similar to the workings and effects obtained by the solid-state imaging device 1 according to the third embodiment.

In addition, in the solid-state imaging device 1, as illustrated in FIGS. 30 to 33, the vertical gate electrode 205 of the transfer transistor 12 is provided between the coupling section 121 and the FD region 25. In such a configuration, a separation distance between the coupling section 121 and the FD region 25 is greater than a separation distance between the vertical gate electrode 205 and the FD region 25.

Therefore, it is possible to separate a path of the electric charge flowing from the photoelectric conversion element 11 to the FD region 25 through the transfer transistor 12 from the coupling section 121 to the FD region 25 side. The path of the electric charge is thus formed at a position sufficiently separated from the position where the coupling section 121 is disposed, which makes it possible to further reduce the intensity of the electric field from the coupling section 121 to the path of the electric charge.

### 5. Fifth Embodiment

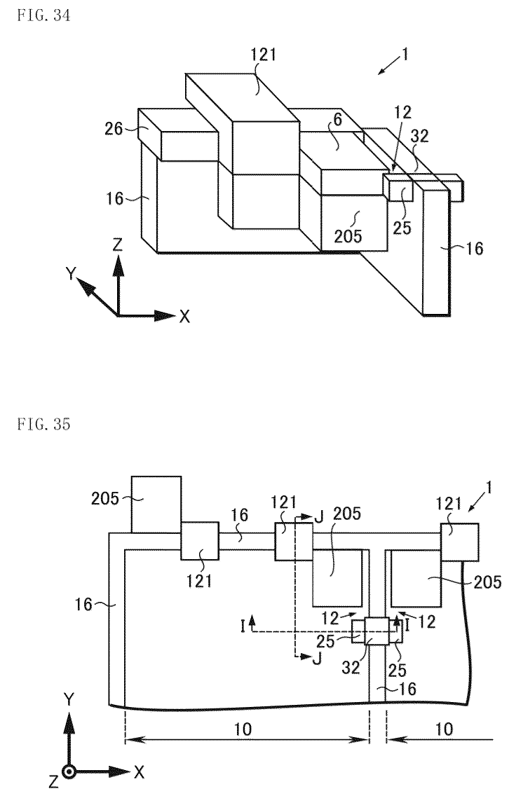

The solid-state imaging device 1 according to a fifth embodiment of the present disclosure will be described with reference to FIGS. 34 to 37.

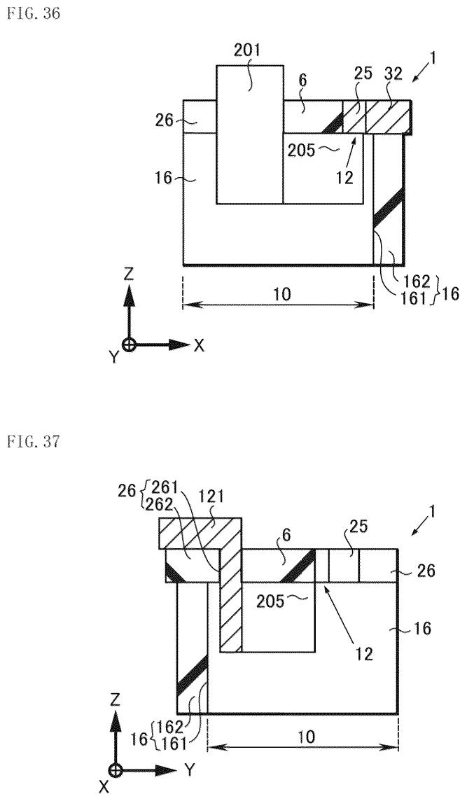

FIG. 34 illustrates an example of a three-dimensional configuration of the pixel 10, the transfer transistor 12, the coupling section 121, and the FD region 25 of the solid-state imaging device 1 according to the fifth embodiment. FIG. 35 illustrates an example of a planar configuration of the pixel 10 and the like illustrated in FIG. 34 as viewed from the arrow Z direction. FIG. 36 illustrates an example of a vertical cross-sectional configuration of the pixel 10 and the like as viewed in the arrow Y direction taken along a line I-I illustrated in FIG. 35. FIG. 37 illustrates an example of a vertical cross-sectional configuration of the pixel 10 and the like as viewed in the arrow X direction taken along a line J-J illustrated in FIG. 35.

As illustrated in FIGS. 34 to 37, in the solid-state imaging device 1 according to the fifth embodiment, the coupling section 121 is provided at a position overlapping with the pixel isolation region 16 extending in the arrow X direction on the second surface 2B side of the base body 2, as with the solid-state imaging device 1 according to the first embodiment.

In contrast, the FD region 25 is provided at a position shifted to the side opposite to the arrow Y direction along the pixel isolation region 16 extending in the arrow Y direction, as with the solid-state imaging device 1 according to the fourth embodiment. The amount by which the FD region 25 is shifted is further increased.

The vertical gate electrode 205 of the transfer transistor 12 extends in the arrow X direction from the part coupled to the coupling section 121, bends in the direction opposite to the arrow Y direction at the extending end, and further extends to the side opposite to the arrow Y direction, as with the solid-state imaging device 1 according to the fourth embodiment. A width dimension of the part of the vertical gate electrode 205 extending to the side opposite to the arrow Y direction is greater than a width dimension of the part extending in the arrow X direction. Therefore, in plan view, the vertical gate electrode 205 is provided along an intersection portion between the pixel isolation region 16 extending in the arrow X direction and the pixel isolation region 16 extending in the arrow Y direction.

In addition, the vertical gate electrode 205 is disposed to be opposed to the FD region 25 in the arrow Y direction.

Components other than the above-described components are the same or substantially the same as the components of the solid-state imaging device 1 according to the fourth embodiment.

### Workings and Effects

The solid-state imaging device 1 according to the fifth embodiment makes it possible to obtain workings and effects similar to the workings and effects obtained by the solid-state imaging device 1 according to the fourth embodiment.

In addition, in the solid-state imaging device 1, as illustrated in FIGS. 34 to 37, the vertical gate electrode 205 of the transfer transistor 12 is provided along the intersection portion between the pixel isolation regions 16. Therefore, the pinning region 20P (see FIGS. 13 to 17) formed along the gate insulating film 205G of the transfer transistor 12 is shared with the unillustrated pinning region provided along the first groove 161 of the pixel isolation region 16. This makes it possible to easily implement the structure of the pinning region of the solid-state imaging device 1, particularly on the second surface 2B side of the base body 2. In addition, it is possible to improve a saturated electric charge quantity (Qs) in the solid-state imaging device 1.

### 6. Sixth Embodiment

The solid-state imaging device 1 according to a sixth embodiment of the present disclosure will be described with reference to FIGS. 38 to 41.

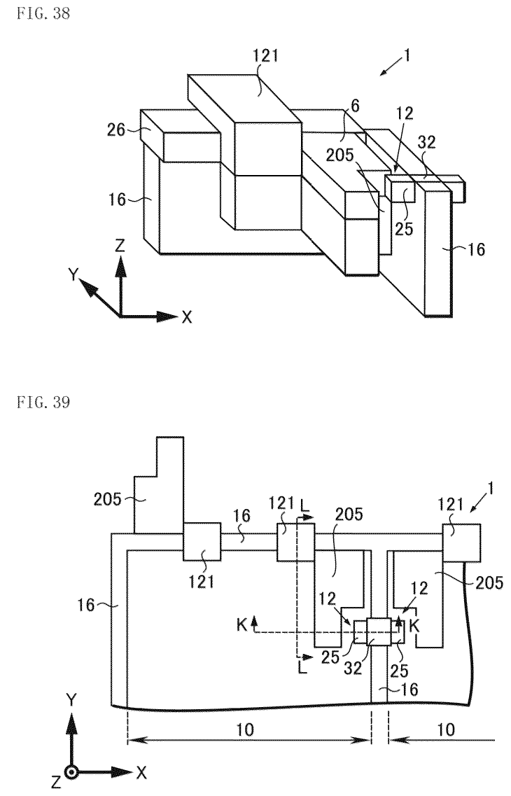

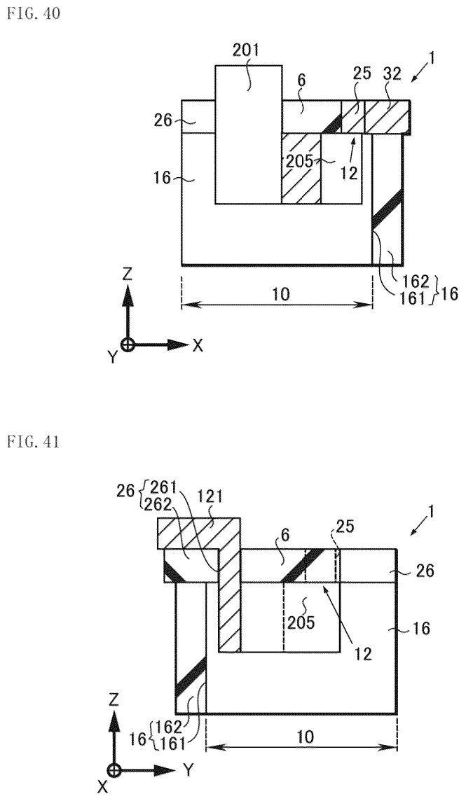

FIG. 38 illustrates an example of a three-dimensional configuration of the pixel 10, the transfer transistor 12, the coupling section 121, and the FD region 25 of the solid-state imaging device 1 according to the sixth embodiment. FIG. 39 illustrates an example of a planar configuration of the pixel 10 and the like illustrated in FIG. 38 as viewed from the arrow Z direction. FIG. 40 illustrates an example of a vertical cross-sectional configuration of the pixel 10 and the like as viewed in the arrow Y direction taken along a line K-K illustrated in FIG. 39. FIG. 41 illustrates an example of a vertical cross-sectional configuration of the pixel 10 and the like as viewed in the arrow X direction taken along a line L-L illustrated in FIG. 39.

As illustrated in FIGS. 38 to 41, in the solid-state imaging device 1 according to the sixth embodiment, the coupling section 121 is provided at a position overlapping with the pixel isolation region 16 extending in the arrow X direction on the second surface 2B side of the base body 2, as with the solid-state imaging device 1 according to the first embodiment.

In contrast, the FD region 25 is provided at a position shifted to the side opposite to the arrow Y direction along the pixel isolation region 16 extending in the arrow Y direction, as with the solid-state imaging device 1 according to the fifth embodiment.

In plan view, the vertical gate electrode 205 of the transfer transistor 12 is provided along the intersection portion between the pixel isolation region 16 extending in the arrow X direction and the pixel isolation region 16 extending in the arrow Y direction, as with the solid-state imaging device 1 according to the fifth embodiment.

Further, the end of the vertical gate electrode 205 extending to the side opposite to the arrow Y direction is formed in a shape notched into an L-shape along two sides of the FD region 25 extending in the arrow Y direction and the arrow X direction. Such a configuration makes it possible to increase the gate width Wg dimension of the transfer transistor 12.

Components other than the above-described components are the same or substantially the same as the components of the solid-state imaging device 1 according to the fifth embodiment.

### Workings and Effects

The solid-state imaging device 1 according to the sixth embodiment makes it possible to obtain workings and effects similar to the workings and effects obtained by the solid-state imaging device 1 according to the fifth embodiment.

In addition, in the solid-state imaging device 1, as illustrated in FIGS. 38 to 41, the vertical gate electrode 205 of the transfer transistor 12 is provided along two sides of the FD region 25. Therefore, it is possible to increase the gate width Wg dimension of the transfer transistor 12, making it possible to improve electric charge transfer efficiency of the transfer transistor 12.

### 7. Seventh Embodiment

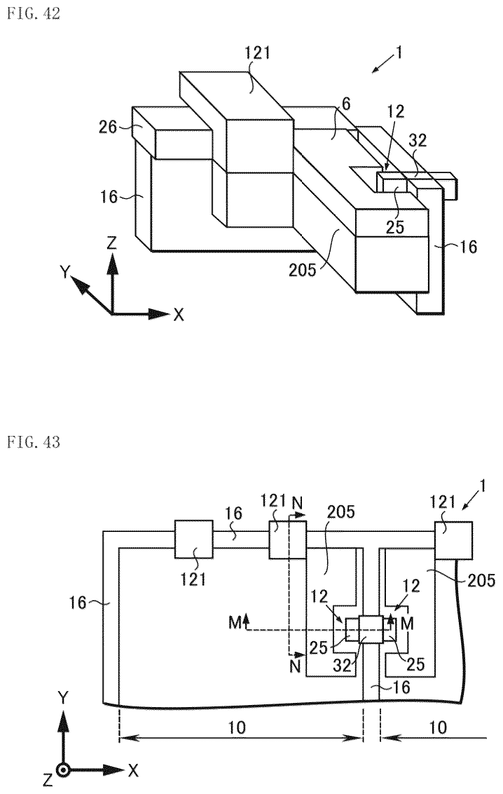

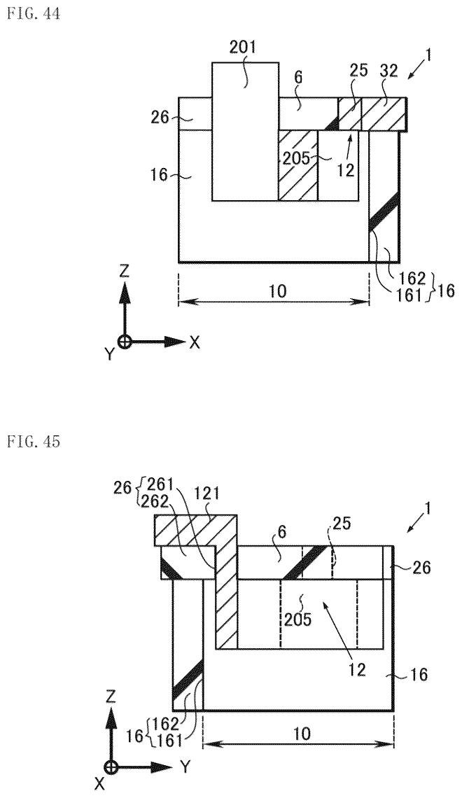

The solid-state imaging device 1 according to a seventh embodiment of the present disclosure will be described with reference to FIGS. 42 to 45.

FIG. 42 illustrates an example of a three-dimensional configuration of the pixel 10, the transfer transistor 12, the coupling section 121, and the FD region 25 of the solid-state imaging device 1 according to the seventh embodiment. FIG. 43 illustrates an example of a planar configuration of the pixel 10 and the like illustrated in FIG. 42 as viewed from the arrow Z direction. FIG. 44 illustrates an example of a vertical cross-sectional configuration of the pixel 10 and the like as viewed in the arrow Y direction taken along a line M-M illustrated in FIG. 43. FIG. 45 illustrates an example of a vertical cross-sectional configuration of the pixel 10 and the like as viewed in the arrow X direction taken along a line N-N illustrated in FIG. 43.

As illustrated in FIGS. 42 to 45, in the solid-state imaging device 1 according to the seventh embodiment, the coupling section 121 is provided at a position overlapping with the pixel isolation region 16 extending in the arrow X direction on the second surface 2B side of the base body 2, as with the solid-state imaging device 1 according to the first embodiment.

In contrast, the FD region 25 is provided at a position shifted to the side opposite to the arrow Y direction along the pixel isolation region 16 extending in the arrow Y direction, as with the solid-state imaging device 1 according to the fifth embodiment.

In plan view, the vertical gate electrode 205 of the transfer transistor 12 is provided along the intersection portion between the pixel isolation region 16 extending in the arrow X direction and the pixel isolation region 16 extending in the arrow Y direction, as with the solid-state imaging device 1 according to the sixth embodiment.

Further, the end of the vertical gate electrode 205 extending to the side opposite to the arrow Y direction is formed in a shape notched into a C-shape along three sides of the FD region 25 extending in the arrow Y direction, in the arrow X direction, and to a side opposite to the arrow X direction. Such a configuration makes it is possible to further increase the gate width Wg dimension of the transfer transistor 12.

Components other than the above-described components are the same or substantially the same as the components of the solid-state imaging device 1 according to the fifth embodiment.

### Workings and Effects

The solid-state imaging device 1 according to the seventh embodiment makes it possible to obtain workings and effects similar to the workings and effects obtained by the solid-state imaging device 1 according to the sixth embodiment.

In addition, in the solid-state imaging device 1, as illustrated in FIGS. 42 to 45, the vertical gate electrode 205 of the transfer transistor 12 is provided along three sides of the FD region 25. Therefore, it is possible to further increase the gate width Wg dimension of the transfer transistor 12, making it possible to further improve the electric charge transfer efficiency of the transfer transistor 12.

### 8. Eighth Embodiment

The solid-state imaging device 1 according to an eighth embodiment of the present disclosure will be described with reference to FIG. 46.

FIG. 46 illustrates an example of a layout configuration in which multiple pixels 10 are arranged.

The solid-state imaging device 1 according to the eighth embodiment is an application example of the solid-state imaging device 1 according to the first embodiment. In the solid-state imaging device 1, one pixel circuit 20 is provided for a total of four pixels 10 including two pixels 10 arranged adjacently in the arrow X direction and two pixels 10 arranged adjacently in the arrow Y direction. In other words, the four pixels 10 are set as the unit pixel BP, and the pixel circuit 20 is provided for each unit pixel BP.

At a position corresponding to one pixel 10 of the unit pixel BP, the amplification transistor 21 is provided on the second surface 2B (see FIGS. 4 and 5) side of the base body 2. In addition, at a position corresponding to another one pixel 10, the selection transistor 22 is provided on the base body 2. In addition, at a position corresponding to another one pixel 10, the FD conversion gain switching transistor 23 is provided on the base body 2. Further, at a position corresponding to another one pixel 10, the reset transistor 24 is provided on the base body 2.

The gate length Lg direction of the transistor 200 such as the amplification transistor 21 is the diagonal direction (see FIG. 2).

Further, the respective transistors 200 of the pixels 10 arranged adjacently in the arrow X direction are formed in a line-symmetric shape with respect to the pixel isolation region 16 between the pixels 10. Similarly, the respective transistors 200 of the pixels 10 arranged adjacently in the arrow Y direction are formed in a line-symmetric shape with respect to the pixel isolation region 16 between the pixels 10.

In the eighth embodiment, the FD regions 25 of the respective pixels 10 of the unit pixel BP are aggregated in a middle portion of the unit pixel BP. Further, the aggregated total of four FD regions 25 are electrically coupled to each other by the shared coupling section 32. In contrast, the base body coupling sections 27 of the respective pixels 10 of the unit pixel BP are provided at respective corner portions of the unit pixel BP. Further, the base body coupling section 27 is electrically coupled, through the shared coupling section 33, to the base body coupling section 27 of the other unit pixel BP adjacent to the unit pixel BP in the arrow X direction or the arrow Y direction.

Components other than the above-described components are the same or substantially the same as the components of the solid-state imaging device 1 according to the first embodiment.

### Workings and Effects

The solid-state imaging device 1 according to the eighth embodiment makes it possible to obtain workings and effects similar to the workings and effects obtained by the solid-state imaging device 1 according to the first embodiment.

### 9. Ninth Embodiment

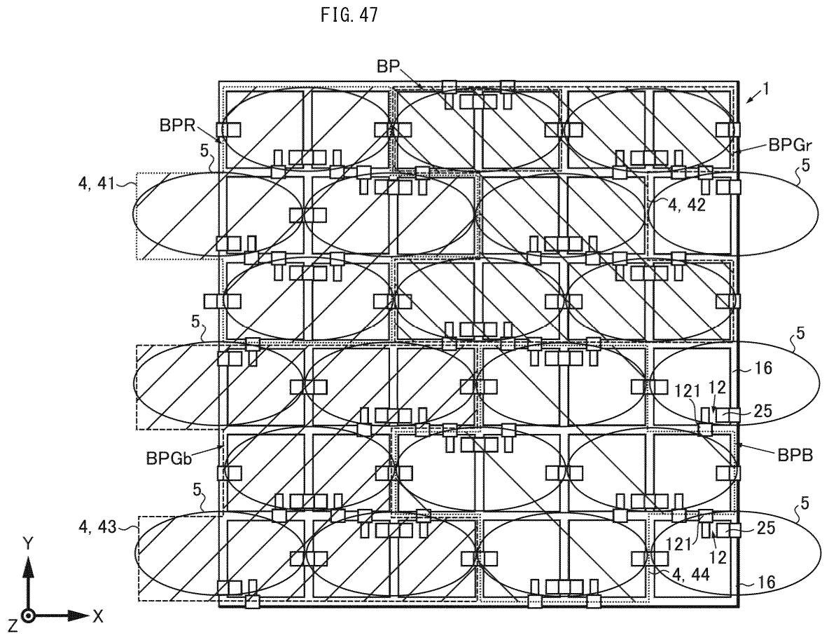

The solid-state imaging device 1 according to a ninth embodiment of the present disclosure will be described with reference to FIG. 47.

FIG. 47 illustrates an example of a layout configuration in which multiple pixels 10 are arranged.

### [Configuration of Solid-State Imaging Device 1]

### (1) Layout Configuration of Pixels 10 of Solid-State Imaging Device 1

In the solid-state imaging device 1 according to the ninth embodiment, two pixels 10 arranged adjacently in the arrow X direction by which the FD regions 25 are shared, as with the solid-state imaging device 1 according to the first embodiment, configure the unit pixel BP. Further, two pixels 10 adjacent to the unit pixel BP in the arrow Y direction and two pixels 10 adjacent to the unit pixel BP in the arrow X direction similarly configure the unit pixel BP. Here, the unit pixel BP adjacent to the unit pixel BP in the arrow Y direction is disposed at a position shifted by one pixel 10 in the arrow X direction.

### (2) Layout Configuration of Pixels 10 and Color Filter 4

A color filter 4 is disposed in the pixel 10. Although not described using a vertical cross section, the color filter 4 is disposed on the first surface 2A side of the base body 2 (see FIGS. 4 and 5).

In the ninth embodiment, the color filter 4 includes red filters 41, green filters (red side) 42, green filters (blue side) 43, and blue filters 44.

In the color filter 4, the red filters 41 and the green filters 42 are each arranged alternately in the arrow X direction. Further, the green filters 43 are arranged adjacent to the red filters 41, on the side opposite to the arrow Y direction. Further, the blue filters 44 are arranged adjacent to the green filters 43 in the arrow X direction. The green filters 43 and the blue filters 44 are each arranged alternately in the arrow X direction.

### (3) Planar Layout Configuration of Red Filter 41 and Blue Filter 44

In the ninth embodiment, a total of eight pixels 10 are constructed as one unit pixel BPR, and the red filter 41 is disposed in the unit pixel BPR.

Specifically, the unit pixel BPR includes four unit pixels BP. In other words, the unit pixel BPR includes one unit pixel BP, two unit pixels BP adjacent in the arrow Y direction and arranged adjacently in the arrow X direction, and one unit pixel BP further adjacent in the arrow Y direction.

In addition, a total of eight pixels 10 are constructed as one unit pixel BPB, and the blue filter 44 is disposed in the unit pixel BPB.

As with the unit pixel BPR, the unit pixel BPB includes four unit pixels BP. In other words, the unit pixel BPB includes one unit pixel BP, two unit pixels BP adjacent in the arrow Y direction and arranged adjacently in the arrow X direction, and one unit pixel BP further adjacent in the arrow Y direction.

### (4) Planar Layout Configuration of Green Filter 42 and Green Filter 43

In the ninth embodiment, a total of ten pixels 10 are constructed as one unit pixel BPGr, and the green filter 42 is disposed in the unit pixel BPGr.

Specifically, the unit pixel BPGr includes five unit pixels BP. In other words, the unit pixel BPGr includes two unit pixels BP arranged adjacently in the arrow X direction, one unit pixel BP adjacent in the arrow Y direction, and two unit pixels BP adjacent in the arrow Y direction and arranged adjacently in the arrow X direction.

In addition, a total of ten pixels 10 are constructed as one unit pixel BPGb, and the green filter 43 is disposed in the unit pixel BPGb.

As with the unit pixel BPGr, the unit pixel BPGb includes five unit pixels BP. In other words, the unit pixel BPGb includes two unit pixels BP arranged adjacently in the arrow X direction, one unit pixel BP adjacent in the arrow Y direction, and two unit pixels BP adjacent in the arrow Y direction and arranged adjacently in the arrow X direction.

### (5) Layout Configuration of Optical Lenses 5

In the ninth embodiment, optical lenses 5 are provided on the first surface 2A side of the base body 2 with the color filter 4 interposed therebetween. The optical lens 5 is provided for each unit pixel BP. In other words, the optical lens 5 has a length of two pixels 10 in the arrow X direction and a length of one pixel 10 in the arrow Y direction. In other words, the optical lens 5 is formed in an elliptical shape with a different aspect ratio in plan view.

Here, the optical lens 5 has a curved light-condensing surface protruding to the side opposite to the arrow Z direction.

Components other than the above-described components are the same or substantially the same as the components of the solid-state imaging device 1 according to the first embodiment.

### Workings and Effects

The solid-state imaging device 1 according to the ninth embodiment makes it possible to obtain workings and effects similar to the workings and effects obtained by the solid-state imaging device 1 according to the first embodiment.

### 10. Tenth Embodiment

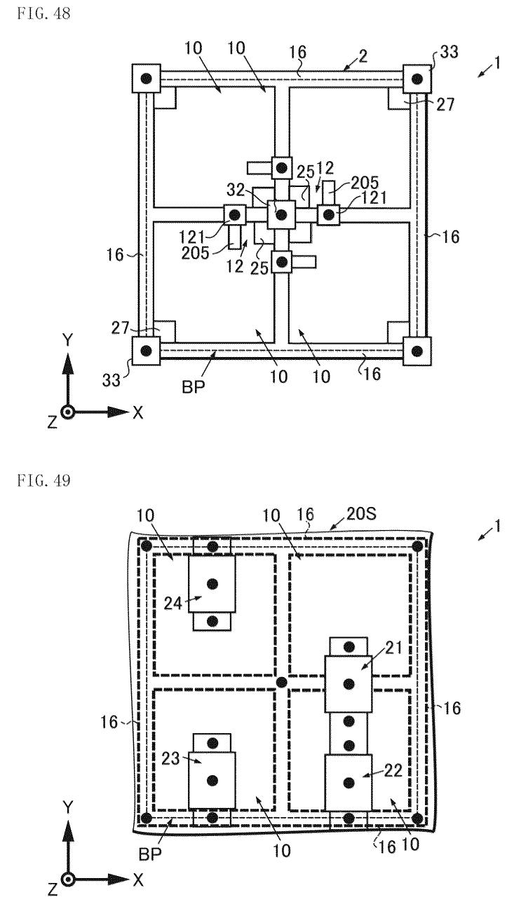

The solid-state imaging device 1 according to a tenth embodiment of the present disclosure will be described with reference to FIGS. 48 and 49.

FIG. 48 illustrates an example of a layout configuration in which multiple pixels 10 are arranged. FIG. 49 illustrates an example of a layout configuration of the transistors 200 included in the pixel circuit 20 and stacked at positions corresponding to the pixels 10.

The solid-state imaging device 1 according to the tenth embodiment adopts a two-layer pixel structure. Specifically, as illustrated in FIG. 48, the base body 2 serves as the first layer, and the base body 2 is provided with the pixels 10 each surrounded by the pixel isolation region 16. The pixel 10 is provided with the unillustrated photoelectric conversion element 11 and the transfer transistor 12.

A second base body 20S is stacked on the second surface 2B side of the base body 2. On the second base body 20S, the transistors 200 included the pixel circuit 20 are provided at the positions corresponding to the pixels 10. That is, the second base body 20S is provided with the amplification transistor 21, the selection transistor 22, the FD conversion gain switching transistor 23, and the reset transistor 24.

Here, the transistor 200 such as the amplification transistor 21 is disposed to have the gate length Lg direction matching the arrow Y direction (or the arrow X direction).

Components other than the above-described components are the same or substantially the same as the components of the solid-state imaging device 1 according to the eighth embodiment.

### Workings and Effects

The solid-state imaging device 1 according to the tenth embodiment makes it possible to obtain workings and effects similar to the workings and effects obtained by the solid-state imaging device 1 according to the eighth embodiment.

### 11. Eleventh Embodiment

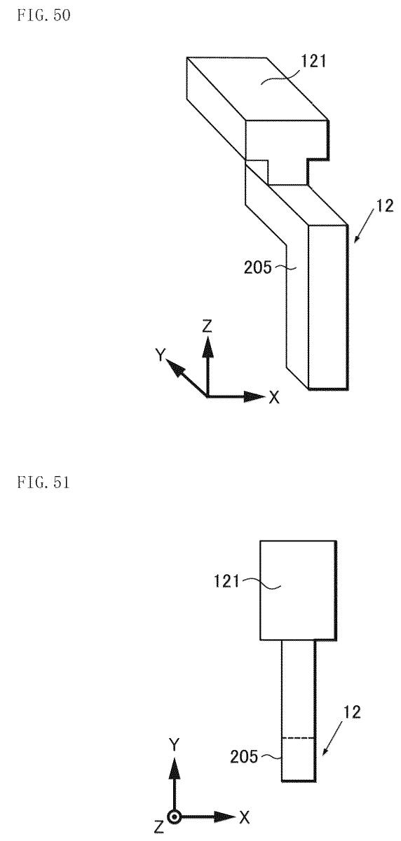

The solid-state imaging device 1 according to an eleventh embodiment of the present disclosure will be described with reference to FIGS. 50 to 53.

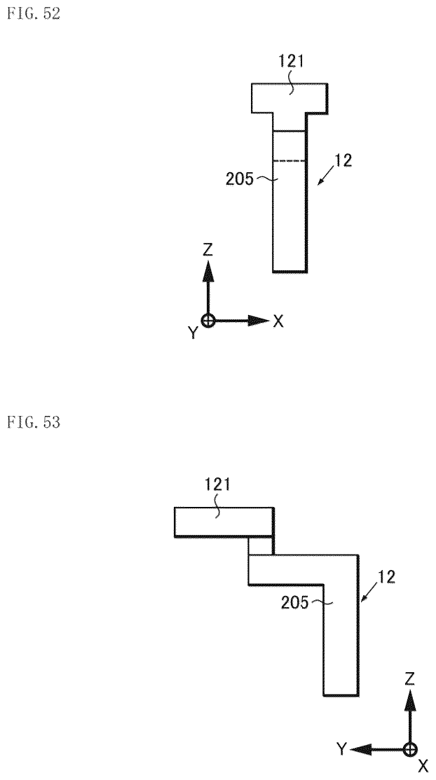

FIG. 50 illustrates an example of a three-dimensional configuration of the transfer transistor 12 and the coupling section 121 of the solid-state imaging device 1 according to the eleventh embodiment. FIG. 51 illustrates an example of a planar configuration of the transfer transistor 12 and the like illustrated in FIG. 50 as viewed from the arrow Z direction. FIG. 52 illustrates an example of a side configuration of the transfer transistor 12 and the like illustrated in FIG. 50 as viewed in the arrow Y direction. FIG. 53 illustrates an example of a side configuration of the transfer transistor 12 and the like illustrated in FIG. 50 as viewed in the arrow X direction.

As illustrated in FIGS. 50 to 53, in the solid-state imaging device 1 according to the eleventh embodiment, a dimension of the vertical gate electrode 205 of the transfer transistor 12 in the arrow Y direction is less than the dimension of the same component of the solid-state imaging device 1 according to the first embodiment. That is, the gate width Wg dimension of the transfer transistor 12 is formed small.

Components other than the above-described components are the same or substantially the same as the components of the solid-state imaging device 1 according to the first embodiment.

### Workings and Effects

The solid-state imaging device 1 according to the eleventh embodiment makes it possible to obtain workings and effects similar to the workings and effects obtained by the solid-state imaging device 1 according to the first embodiment.

In addition, because the gate width Wg of the transfer transistor 12 is made small in the solid-state imaging device 1, it is possible to improve the saturated electric charge quantity (Qs).

### First Modification Example

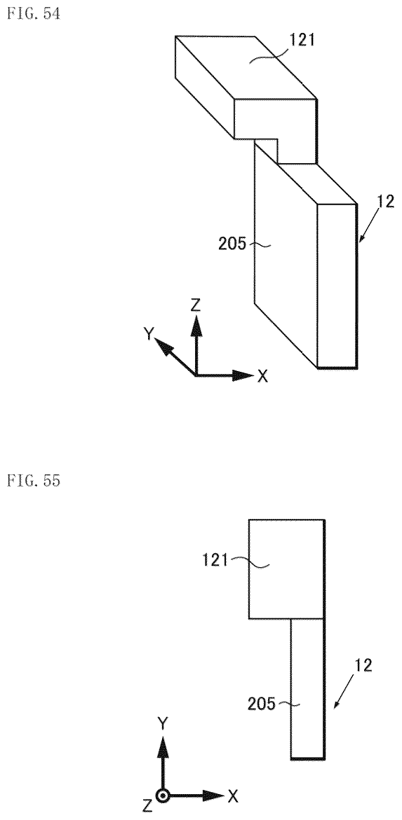

The solid-state imaging device 1 according to a first modification example of the eleventh embodiment will be described with reference to FIGS. 54 to 57.

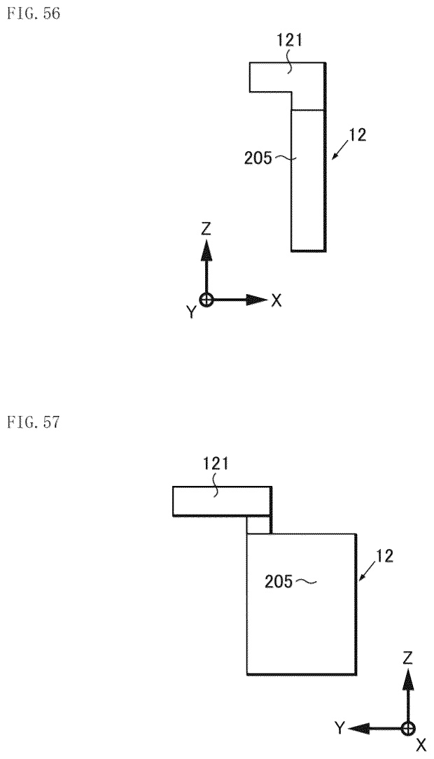

FIG. 54 illustrates an example of a three-dimensional configuration of the transfer transistor 12 and the coupling section 121 of the solid-state imaging device 1 according to the first modification example of the eleventh embodiment. FIG. 55 illustrates an example of a planar configuration of the transfer transistor 12 and the like illustrated in FIG. 54 as viewed from the arrow Z direction. FIG. 56 illustrates an example ofa side configuration of the transfer transistor 12 and the like illustrated in FIG. 54 as viewed in the arrow Y direction. FIG. 57 illustrates an example of a side configuration of the transfer transistor 12 and the like illustrated in FIG. 54 as viewed in the arrow X direction.

As illustrated in FIGS. 54 to 57, in the first solid-state imaging device 1 according to the first modification example of the eleventh embodiment, within a width dimension of the coupling section 121 in the arrow X direction, the vertical gate electrode 205 of the transfer transistor 12 is provided on the arrow X direction side. That is, the vertical gate electrode 205 is disposed close to the FD region 25.

Components other than the above-described components are the same or substantially the same as the components of the solid-state imaging device 1 according to the first embodiment.

### Workings and Effects

The solid-state imaging device 1 according to the first modification example of the eleventh embodiment makes it possible to obtain workings and effects similar to the workings and effects obtained by the solid-state imaging device 1 according to the first embodiment.

In addition, in the solid-state imaging device 1, the vertical gate electrode 205 of the transfer transistor 12 is disposed close to the FD region 25. Therefore, the FD region 25 is disposed at a position sufficiently separated from the position where the coupling section 121 is disposed, which makes it possible to reduce the intensity of the electric field from the coupling section 121 to the FD region 25.

### Second Modification Example

The solid-state imaging device 1 according to a second modification example of the eleventh embodiment will be described with reference to FIGS. 58 to 61.

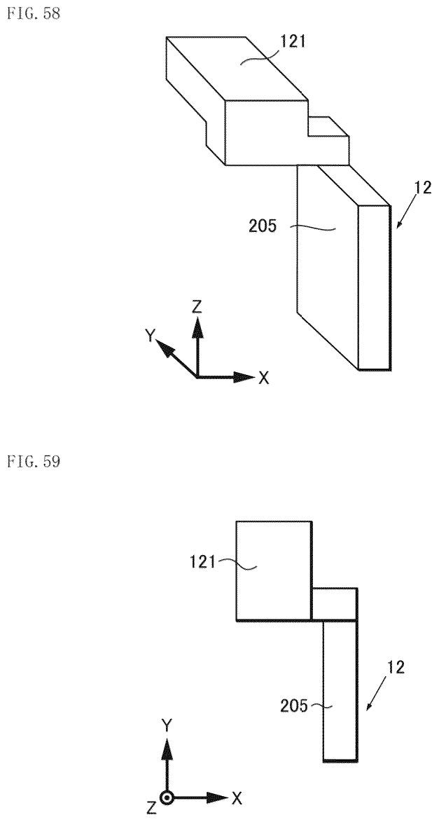

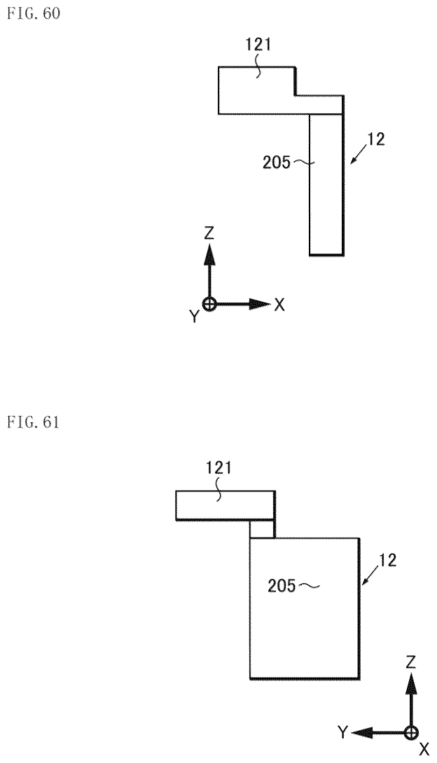

FIG. 58 illustrates an example of a three-dimensional configuration of the transfer transistor 12 and the coupling section 121 of the solid-state imaging device 1 according to the second modification example of the eleventh embodiment. FIG. 59 illustrates an example of a planar configuration of the transfer transistor 12 and the like illustrated in FIG. 58 as viewed from the arrow Z direction. FIG. 60 illustrates an example of a side configuration of the transfer transistor 12 and the like illustrated in FIG. 58 as viewed in the arrow Y direction. FIG. 61 illustrates an example of a side configuration of the transfer transistor 12 and the like illustrated in FIG. 58 as viewed in the arrow X direction.

As illustrated in FIGS. 58 to 61, in the solid-state imaging device 1 according to the second modification example of the eleventh embodiment, a portion of the coupling section 121 extends in the arrow X direction, and the vertical gate electrode 205 of the transfer transistor 12 is coupled to the extending part. That is, the vertical gate electrode 205 is disposed close to the FD region 25.

Components other than the above-described components are the same or substantially the same as the components of the solid-state imaging device 1 according to the first modification example of the eleventh embodiment.

### Workings and Effects

The solid-state imaging device 1 according to the second modification example of the eleventh embodiment makes it possible to obtain workings and effects similar to the workings and effects obtained by the solid-state imaging device 1 according to the first modification example of the eleventh embodiment.

### Third Modification Example

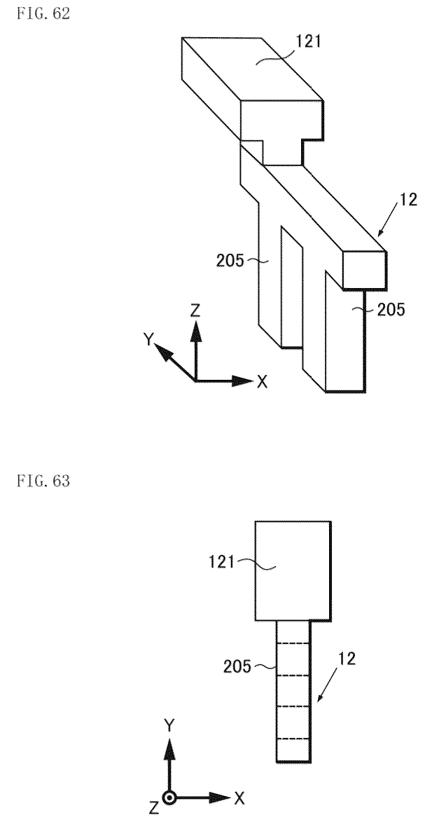

The solid-state imaging device 1 according to a third modification example of the eleventh embodiment will be described with reference to FIGS. 62 to 65.

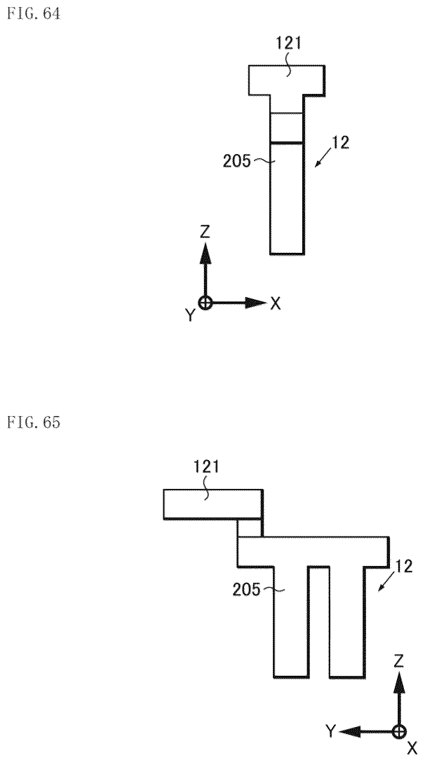

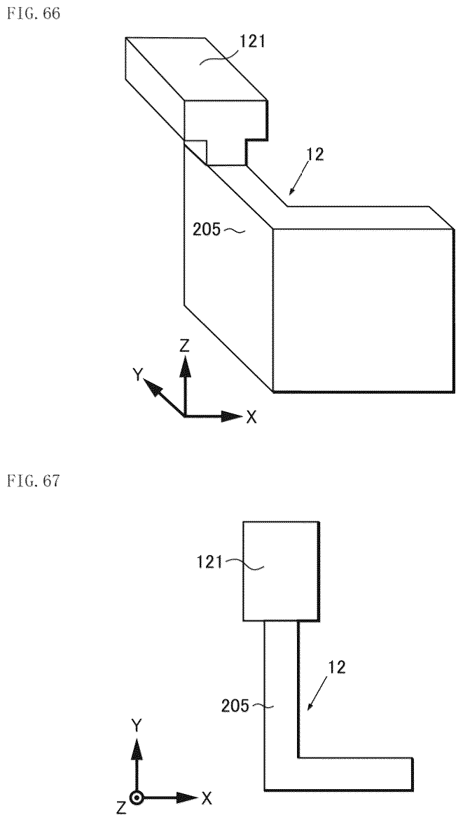

FIG. 62 illustrates an example of a three-dimensional configuration of the transfer transistor 12 and the coupling section 121 of the solid-state imaging device 1 according to the third modification example of the eleventh embodiment. FIG. 63 illustrates an example of a planar configuration of the transfer transistor 12 and the like illustrated in FIG. 62 as viewed from the arrow Z direction. FIG. 64 illustrates an example of a side configuration of the transfer transistor 12 and the like illustrated in FIG. 62 as viewed in the arrow Y direction. FIG. 65 illustrates an example of a side configuration of the transfer transistor 12 and the like illustrated in FIG. 62 as viewed in the arrow X direction.

As illustrated in FIGS. 62 to 65, in the solid-state imaging device 1 according to the third modification example of the eleventh embodiment, the vertical gate electrode 205 of the transfer transistor 12 is branched into multiple parts electrically coupled in parallel to each other. Here, the vertical gate electrode 205 is branched into two parts extending to the side opposite to the arrow Z direction and separated from each other in the arrow Y direction. That is, the transfer transistor 12 has the gate width Wg dimension substantially extended.

Components other than the above-described components are the same or substantially the same as the components of the solid-state imaging device 1 according to the first modification example of the eleventh embodiment.

### Workings and Effects

The solid-state imaging device 1 according to the third modification example of the eleventh embodiment makes it possible to obtain workings and effects similar to the workings and effects obtained by the solid-state imaging device 1 according to the first modification example of the eleventh embodiment.

In addition, it is possible to increase the gate width Wg dimension of the transfer transistor 12 in the solid-state imaging device 1, which makes it possible to improve the electric charge transfer efficiency of the transfer transistor 12.

### Fourth Modification Example

The solid-state imaging device 1 according to a fourth modification example of the eleventh embodiment will be described with reference to FIGS. 66 to 69.

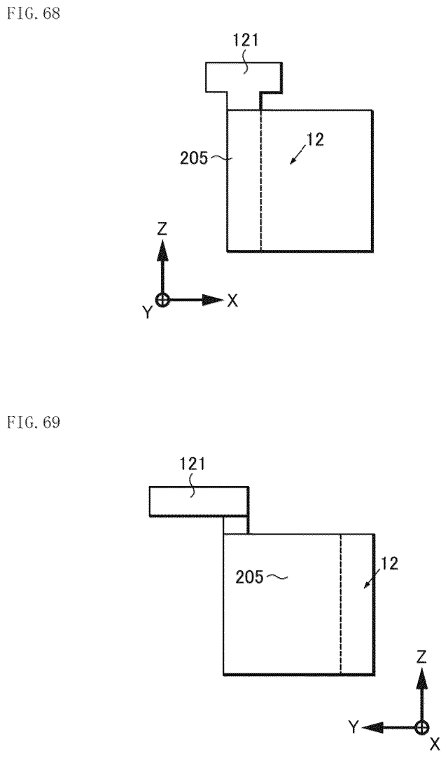

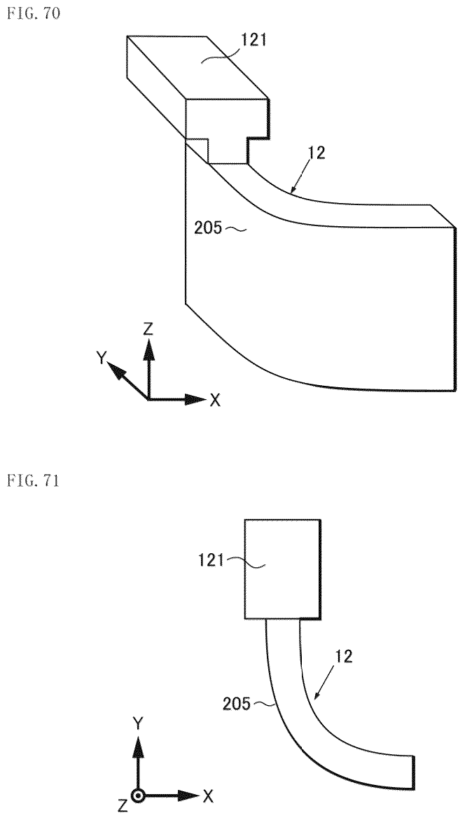

FIG. 66 illustrates an example of a three-dimensional configuration of the transfer transistor 12 and the coupling section 121 of the solid-state imaging device 1 according to the fourth modification example of the eleventh embodiment. FIG. 67 illustrates an example of a planar configuration of the transfer transistor 12 and the like illustrated in FIG. 66 as viewed from the arrow Z direction. FIG. 68 illustrates an example of a side configuration of the transfer transistor 12 and the like illustrated in FIG. 66 as viewed in the arrow Y direction. FIG. 69 illustrates an example of a side configuration of the transfer transistor 12 and the like illustrated in FIG. 66 as viewed in the arrow X direction.

As illustrated in FIGS. 66 to 69, in the solid-state imaging device 1 according to the fourth modification example of the eleventh embodiment, the vertical gate electrode 205 of the transfer transistor 12 extends from the part coupled to the coupling section 121 to the side opposite to the arrow Y direction, and bends from the extending part to extend in the arrow X direction. The vertical gate electrode 205 is formed just along two sides of the FD region 25. The vertical gate electrode 205 is formed in an L-shape in plan view. That is, the transfer transistor 12 has the gate width Wg dimension substantially extended.

Components other than the above-described components are the same or substantially the same as the components of the solid-state imaging device 1 according to the first modification example of the eleventh embodiment.

### Workings and Effects

The solid-state imaging device 1 according to the fourth modification example of the eleventh embodiment makes it possible to obtain workings and effects similar to the workings and effects obtained by the solid-state imaging device 1 according to the third modification example of the eleventh embodiment.

### Fifth Modification Example

The solid-state imaging device 1 according to a fifth modification example of the eleventh embodiment will be described with reference to FIGS. 70 to 73.

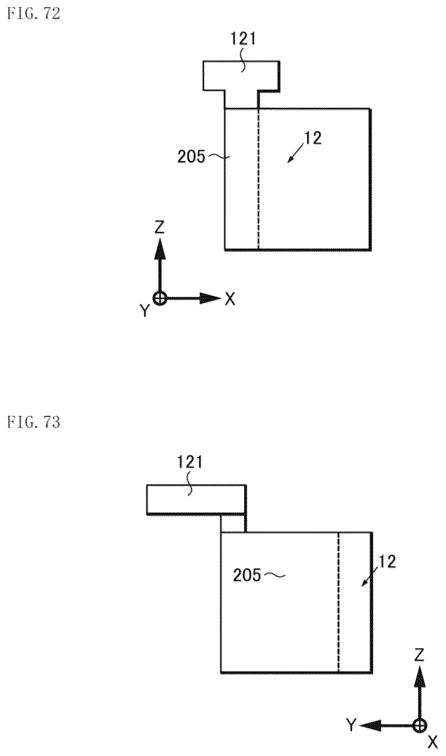

FIG. 70 illustrates an example of a three-dimensional configuration of the transfer transistor 12 and the coupling section 121 of the solid-state imaging device 1 according to the fifth modification example of the eleventh embodiment. FIG. 71 illustrates an example of a planar configuration of the transfer transistor 12 and the like illustrated in FIG. 70 as viewed from the arrow Z direction. FIG. 72 illustrates an example of a side configuration of the transfer transistor 12 and the like illustrated in FIG. 70 as viewed in the arrow Y direction. FIG. 73 illustrates an example of a side configuration of the transfer transistor 12 and the like illustrated in FIG. 70 as viewed in the arrow X direction.

As illustrated in FIGS. 70 to 73, in the solid-state imaging device 1 according to the fifth modification example of the eleventh embodiment, the vertical gate electrode 205 of the transfer transistor 12 extends from the part coupled to the coupling section 121 to the side opposite to the arrow Y direction, and extends in the arrow X direction while curving. The vertical gate electrode 205 is formed along two sides of the FD region 25. The vertical gate electrode 205 is formed in a C-shape in plan view. That is, the transfer transistor 12 has the gate width Wg dimension substantially extended.

Components other than the above-described components are the same or substantially the same as the components of the solid-state imaging device 1 according to the first modification example of the eleventh embodiment.

### Workings and Effects

The solid-state imaging device 1 according to the fifth modification example of the eleventh embodiment makes it possible to obtain workings and effects similar to the workings and effects obtained by the solid-state imaging device 1 according to the third modification example of the eleventh embodiment.

### Sixth Modification Example

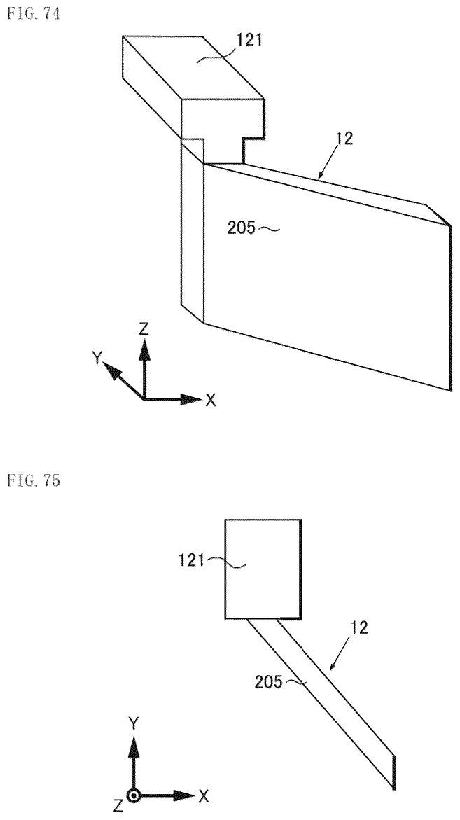

The solid-state imaging device 1 according to a sixth modification example of the eleventh embodiment will be described with reference to FIGS. 74 to 77.

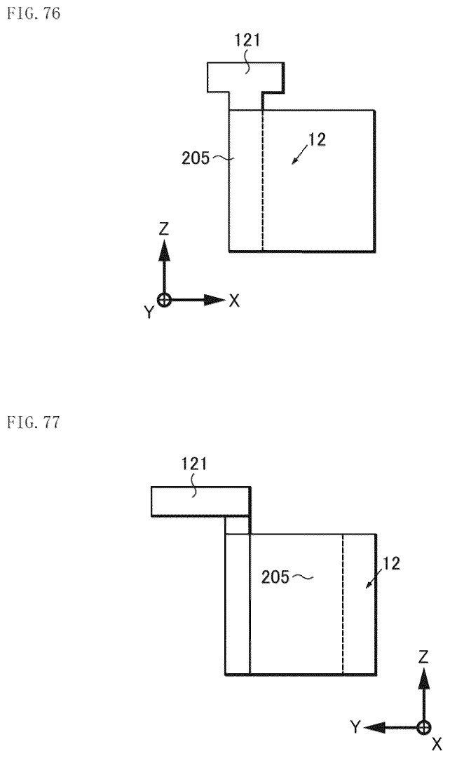

FIG. 74 illustrates an example of a three-dimensional configuration of the transfer transistor 12 and the coupling section 121 of the solid-state imaging device 1 according to the sixth modification example of the eleventh embodiment. FIG. 75 illustrates an example of a planar configuration of the transfer transistor 12 and the like illustrated in FIG. 74 as viewed from the arrow Z direction. FIG. 76 illustrates an example of a side configuration of the transfer transistor 12 and the like illustrated in FIG. 74 as viewed in the arrow Y direction. FIG. 77 illustrates an example of a side configuration of the transfer transistor 12 and the like illustrated in FIG. 74 as viewed in the arrow X direction.

As illustrated in FIGS. 74 to 77, in the solid-state imaging device 1 according to the sixth modification example of the eleventh embodiment, the vertical gate electrode 205 of the transfer transistor 12 extends from the part coupled to the coupling section 121 in a diagonal direction toward the side opposite to the arrow Y direction and the arrow X direction. Here, the vertical gate electrode 205 extends with an inclination of 45 degrees with respect to the arrow Y direction or the arrow X direction. The vertical gate electrode 205 is formed along two sides of the FD region 25. That is, the transfer transistor 12 has the gate width Wg dimension substantially extended.

Components other than the above-described components are the same or substantially the same as the components of the solid-state imaging device 1 according to the first modification example of the eleventh embodiment.

### Workings and Effects

The solid-state imaging device 1 according to the sixth modification example of the eleventh embodiment makes it possible to obtain workings and effects similar to the workings and effects obtained by the solid-state imaging device 1 according to the third modification example of the eleventh embodiment.

### Seventh Modification Example

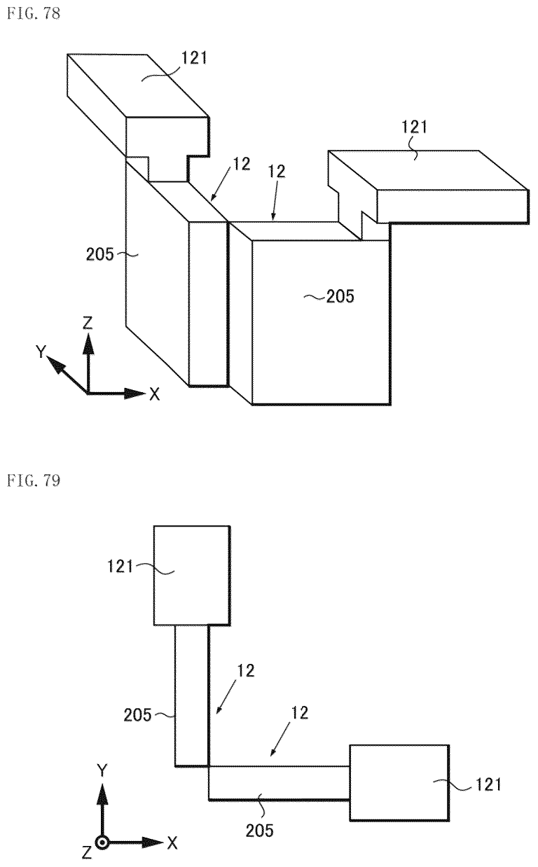

The solid-state imaging device 1 according to a seventh modification example of the eleventh embodiment will be described with reference to FIGS. 78 to 81.

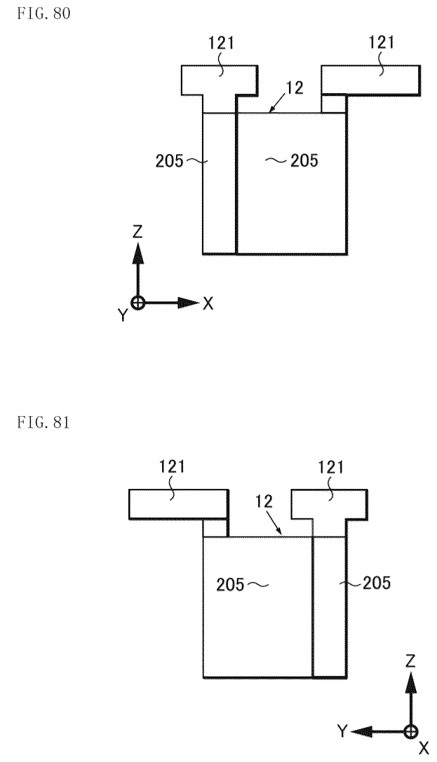

FIG. 78 illustrates an example of a three-dimensional configuration of the transfer transistor 12 and the coupling section 121 of the solid-state imaging device 1 according to the seventh modification example of the eleventh embodiment. FIG. 79 illustrates an example of a planar configuration of the transfer transistor 12 and the like illustrated in FIG. 78 as viewed from the arrow Z direction. FIG. 80 illustrates an example of a side configuration of the transfer transistor 12 and the like illustrated in FIG. 78 as viewed in the arrow Y direction. FIG. 81 illustrates an example of a side configuration of the transfer transistor 12 and the like illustrated in FIG. 78 as viewed in the arrow X direction.

As illustrated in FIGS. 78 to 81, in the solid-state imaging device 1 according to the seventh modification example of the eleventh embodiment, the transfer transistor 12 includes two vertical gate electrodes 205. One of the vertical gate electrodes 205 is electrically coupled to the coupling section 121 provided at a position overlapping the pixel isolation region 16 extending in the arrow X direction, and extends from the coupled part to the side opposite to the arrow Y direction. The other vertical gate electrode 205 is electrically coupled to the coupling section 121 provided at a position overlapping the pixel isolation region 16 extending in the arrow Y direction, and extends from the coupled part to the side opposite to the arrow X direction. The two vertical gate electrodes 205 are electrically coupled in parallel to each other.

The two vertical gate electrodes 205 are formed along respective two sides of the FD region 25. That is, the transfer transistor 12 has the gate width Wg dimension substantially extended.

Components other than the above-described components are the same or substantially the same as the components of the solid-state imaging device 1 according to the first modification example of the eleventh embodiment.

### Workings and Effects

The solid-state imaging device 1 according to the seventh modification example of the eleventh embodiment makes it possible to obtain workings and effects similar to the workings and effects obtained by the solid-state imaging device 1 according to the third modification example of the eleventh embodiment.

### Eighth Modification Example

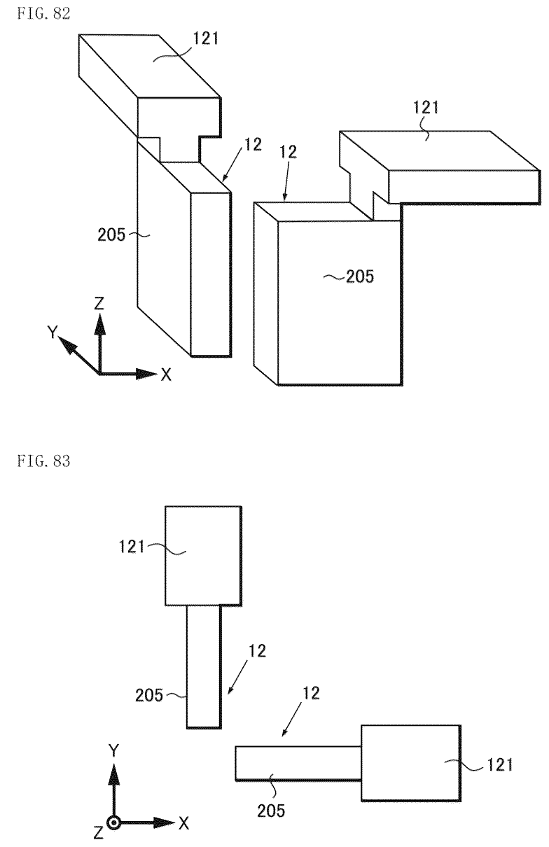

The solid-state imaging device 1 according to an eighth modification example of the eleventh embodiment will be described with reference to FIGS. 82 to 85.

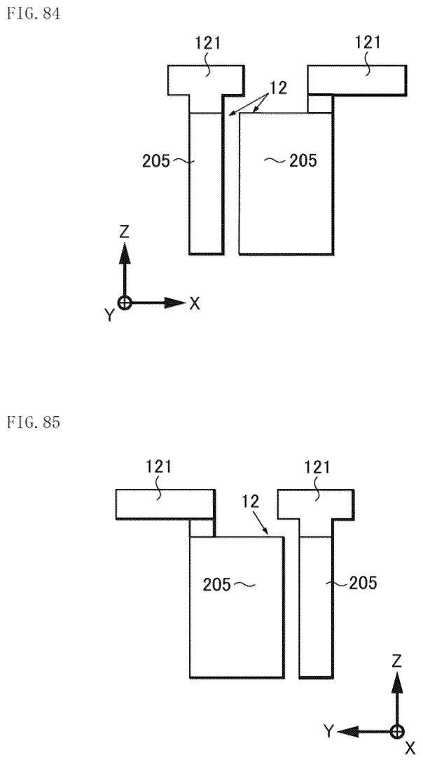

FIG. 82 illustrates an example of a three-dimensional configuration of the transfer transistor 12 and the coupling section 121 of the solid-state imaging device 1 according to the eighth modification example of the eleventh embodiment. FIG. 83 illustrates an example of a planar configuration of the transfer transistor 12 and the like illustrated in FIG. 82 as viewed from the arrow Z direction. FIG. 84 illustrates an example of a side configuration of the transfer transistor 12 and the like illustrated in FIG. 82 as viewed in the arrow Y direction. FIG. 85 illustrates an example of a side configuration of the transfer transistor 12 and the like illustrated in FIG. 82 as viewed in the arrow X direction.

As illustrated in FIGS. 82 to 85, in the solid-state imaging device 1 according to the eighth modification example of the eleventh embodiment, the transfer transistor 12 includes two vertical gate electrodes 205, as with the solid-state imaging device 1 according to the seventh modification example. One of the vertical gate electrodes 205 is electrically coupled to the coupling section 121 provided at a position overlapping the pixel isolation region 16 extending in the arrow X direction, and extends from the coupled part to the side opposite to the arrow Y direction. The other vertical gate electrode 205 is electrically coupled to the coupling section 121 provided at a position overlapping the pixel isolation region 16 extending in the arrow Y direction, and extends from the coupled part to the side opposite to the arrow X direction. The two vertical gate electrodes 205 are electrically coupled in parallel to each other. Further, the two vertical gate electrodes 205 are slightly separated from each other.

The two vertical gate electrodes 205 are formed along respective two sides of the FD region 25. Further, because the two vertical gate electrodes 205 are slightly separated from each other, they are used as an electric charge transfer path. That is, the transfer transistor 12 has the gate width Wg dimension substantially extended further.

Components other than the above-described components are the same or substantially the same as the components of the solid-state imaging device 1 according to the seventh modification example of the eleventh embodiment.

### Workings and Effects

The solid-state imaging device 1 according to the eighth modification example of the eleventh embodiment makes it possible to obtain workings and effects similar to the workings and effects obtained by the solid-state imaging device 1 according to the seventh modification example of the eleventh embodiment.

### Ninth Modification Example

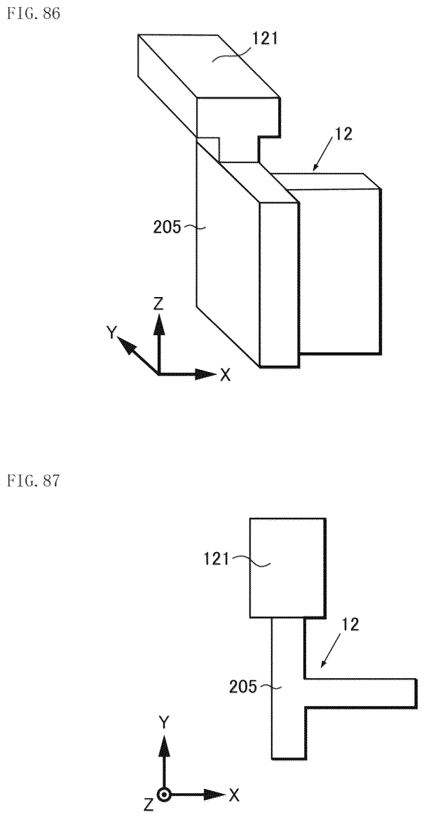

The solid-state imaging device 1 according to a ninth modification example of the eleventh embodiment will be described with reference to FIGS. 86 to 89.

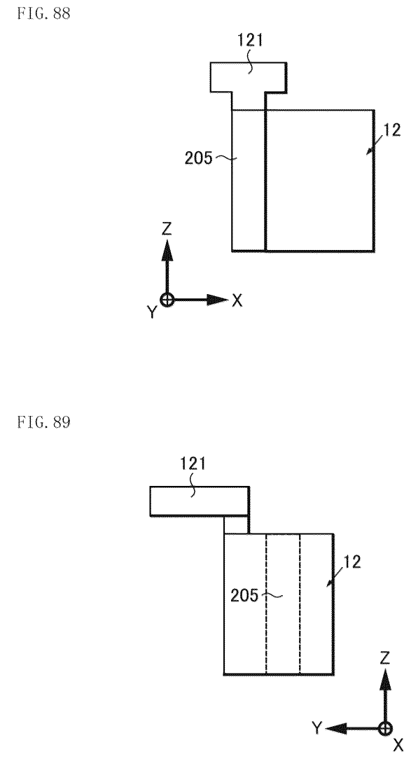

FIG. 86 illustrates an example of a three-dimensional configuration of the transfer transistor 12 and the coupling section 121 of the solid-state imaging device 1 according to the ninth modification example of the eleventh embodiment. FIG. 87 illustrates an example of a planar configuration of the transfer transistor 12 and the like illustrated in FIG. 86 as viewed from the arrow Z direction. FIG. 88 illustrates an example ofa side configuration of the transfer transistor 12 and the like illustrated in FIG. 86 as viewed in the arrow Y direction. FIG. 89 illustrates an example of a side configuration of the transfer transistor 12 and the like illustrated in FIG. 86 as viewed in the arrow X direction.

As illustrated in FIGS. 86 to 89, the solid-state imaging device 1 according to the ninth modification example of the eleventh embodiment is an application example of the solid-state imaging device 1 according to the first modification example of the eleventh embodiment. That is, the vertical gate electrode 205 of the transfer transistor 12 extends in the arrow Y direction, and protrudes in the arrow X direction at an intermediate portion in the extending direction. The protruding part of the vertical gate electrode 205 is disposed close to the FD region 25. The vertical gate electrode 205 is formed in a T-shape in plan view.

Components other than the above-described components are the same or substantially the same as the components of the solid-state imaging device 1 according to the first modification example of the eleventh embodiment.

### Workings and Effects

The solid-state imaging device 1 according to the ninth modification example of the eleventh embodiment makes it possible to obtain workings and effects similar to the workings and effects obtained by the solid-state imaging device 1 according to the first modification example of the eleventh embodiment.

### 12. Application Example to Mobile Body

The technology (present technology) according to the present disclosure is applicable to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a vessel, or a robot.

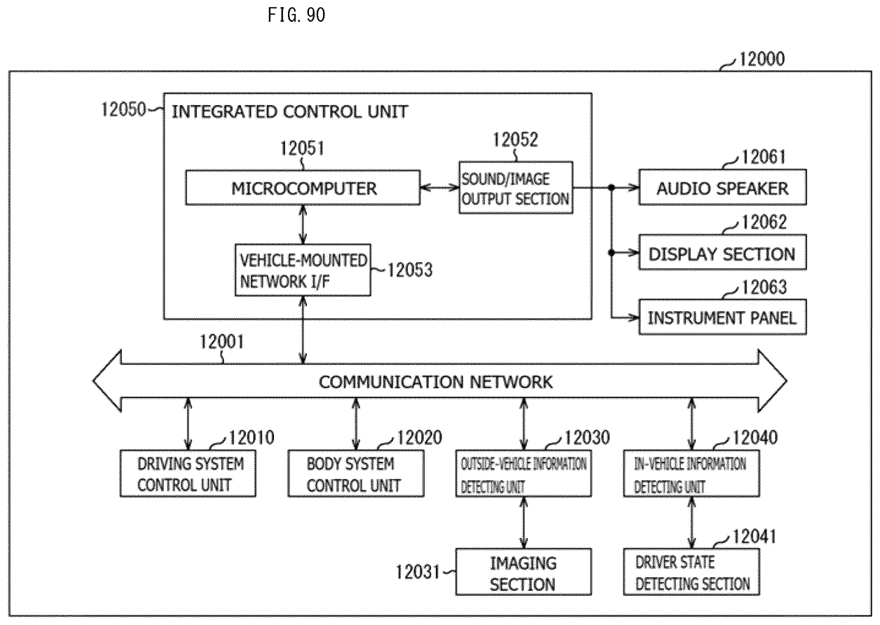

FIG. 90 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 90, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 90, an audio speaker 12061, a display section 12062, and an instrument panel 12063 are illustrated as the output device. The display section 12062 may, for example, include at least one of an on-board display and a head-up display.

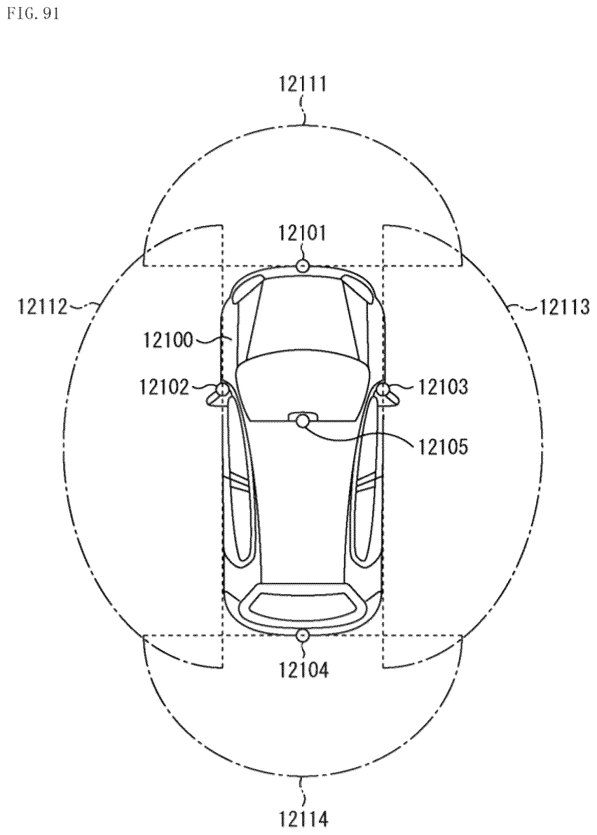

FIG. 91 is a diagram depicting an example of the installation position of the imaging section 12031.

In FIG. 91, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 91 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure may be applied has been described above. The technology according to the present disclosure may be applied to the imaging section 12031 among the components described above. It is possible to implement the imaging section 12031 with a simpler configuration by applying the technology according to the present disclosure to the imaging section 12031.

### 13. Other Embodiments

The present technology is not limited to the above embodiments, but may be modified in a variety of ways without departing from the scope of the present technology.

For example, among the solid-state imaging devices according to the first to eleventh embodiments, the solid-state imaging devices according to two or more embodiments may be combined.

In addition, in the present technology, for example, in the solid-state imaging device according to the ninth embodiment, the number of pixels included in the unit pixel and the arrangement layout of the unit pixels may be appropriately changed.

In addition, the present technology is not limited to imaging applications, and is widely applicable to a light receiving device, a photoelectric conversion device, a photodetection device, and the like used in sensing applications, etc. Further, the solid-state imaging device may use, as well as incident light of visible light, incident light such as infrared light, ultraviolet light, or electromagnetic waves. In addition, the present technology may have a configuration in which a band-pass filter or the like is optionally provided above the light incident side of the photoelectric conversion element, and desired incident light is received.

In the present disclosure, the solid-state imaging device includes the pixel, the transfer transistor, and the pixel isolation region. The pixel is provided on the first surface side as the light incident side of the base body, and includes the photoelectric conversion element that converts light into electric charge. The transfer transistor is provided on the second surface side of the base body on the side opposite to the first surface, at a position corresponding to the pixel, and has one main electrode electrically coupled to the photoelectric conversion element. The pixel isolation region is provided in the thickness direction of the base body to surround the photoelectric conversion element and the transfer transistor, and provides electrical and optical isolation.

Here, the solid-state imaging device further includes the coupling section. The coupling section is provided at a position overlapping the pixel isolation region on the second surface side of the base body. The coupling section electrically couples the gate electrode of the transfer transistor and the control signal line to each other.

Therefore, it is possible to effectively suppress or prevent the spread of an electric field from the coupling section to the second surface side of the base body, which makes it possible to reduce intensity of the electric field from the coupling section.

### Configuration of Present Technology

The present technology has the following configurations.

According to the present technology with the following configurations, it is possible to reduce the intensity of the electric field generated around the control signal line in the solid-state imaging device.

(1)

A solid-state imaging device including:
a pixel that is provided on a first surface side as a light incident side of a base body, and includes a photoelectric conversion element that converts light into electric charge;
a transfer transistor that is provided on a second surface side of the base body on a side opposite to the first surface, at a position corresponding to the pixel, and has one main electrode electrically coupled to the photoelectric conversion element;
a pixel isolation region that is provided in a thickness direction of the base body to surround the photoelectric conversion element and the transfer transistor, and provides electrical and optical isolation; and
a coupling section that is provided at a position overlapping the pixel isolation region on the second surface side, and electrically couples a gate electrode of the transfer transistor and a control signal line to each other.
   (2)

The solid-state imaging device according to (1), in which a floating diffusion region electrically coupled to another main electrode of the transfer transistor is provided in a region surrounded by the pixel isolation region.

(3)

The solid-state imaging device according to (2), in which
the pixel isolation region includes a first pixel isolation region extending in a first direction, and a second pixel isolation region extending in a second direction intersecting the first direction,
the coupling section is provided at a position overlapping one of the first pixel isolation region and the second pixel isolation region, and
the floating diffusion region is provided at a position that is close to an intersection between the first pixel isolation region and the second pixel isolation region or another of the first pixel isolation region and the second pixel isolation region.
   (4)

The solid-state imaging device according to (2) or (3), in which the gate electrode is provided along a side surface of the floating diffusion region.

(5)

The solid-state imaging device according to (4), in which
the floating diffusion region is formed in a rectangular shape as viewed from the second surface side, and
the gate electrode is provided along the side surface of one or more sides of the rectangular shape of the floating diffusion region.
   (6)

The solid-state imaging device according to any one of (1) to (5), in which the gate electrode includes one or more parts extending in the thickness direction of the base body.

(7)

The solid-state imaging device according to any one of (2) to (5), in which the gate electrode is provided between the coupling section and the floating diffusion region.

(8)

The solid-state imaging device according to any one of (2) to (5) and (7), in which a separation distance between the coupling section and the floating diffusion region is greater than a separation distance between the gate electrode and the floating diffusion region.

(9)

The solid-state imaging device according to any one of (2) to (5), (7), and (8), in which a third surface of the gate electrode on the second surface side is formed at a same position as a fourth surface of the floating diffusion region on the first surface side, or a position on the first surface side with respect to the fourth surface, in the thickness direction of the base body.

(10)

The solid-state imaging device according to (9), in which an insulator is provided toward the second surface side on the third surface of the gate electrode.

(11)

The solid-state imaging device according to (10), in which the insulator is embedded at a position corresponding to the third surface, in a groove formed from the second surface of the base body toward the first surface side.

(12)

The solid-state imaging device according to (10) or (11), in which the insulator is formed in a same layer and includes a same insulating material as an interlayer insulating film provided on the second surface of the base body.

(13)

The solid-state imaging device according to (3), in which
a plurality of the pixels is arranged in the first direction and the second direction with the pixel isolation region interposed therebetween, and
the floating diffusion regions of the respective pixels arranged adjacently in the first direction or the second direction are electrically coupled to each other with a shared coupling section interposed therebetween.

This application claims the benefit of Japanese Priority Patent Application JP2022-037313 filed with the Japan Patent Office on Mar. 10, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A solid-state imaging device, comprising:
a pixel that is provided on a first surface side as a light incident side of a base body, and includes a photoelectric conversion element that converts light into electric charge;
a transfer transistor that is provided on a second surface side of the base body on a side opposite to the first surface, at a position corresponding to the pixel, and has one main electrode electrically coupled to the photoelectric conversion element;
a pixel isolation region that is provided in a thickness direction of the base body to surround the photoelectric conversion element and the transfer transistor, and provides electrical and optical isolation; and
a coupling section that is provided at a position overlapping the pixel isolation region on the second surface side, and electrically couples a gate electrode of the transfer transistor and a control signal line to each other.

2. The solid-state imaging device according to claim 1, wherein a floating diffusion region electrically coupled to another main electrode of the transfer transistor is provided in a region surrounded by the pixel isolation region.

3. The solid-state imaging device according to claim 2, wherein
the pixel isolation region includes a first pixel isolation region extending in a first direction, and a second pixel isolation region extending in a second direction intersecting the first direction,
the coupling section is provided at a position overlapping one of the first pixel isolation region and the second pixel isolation region, and
the floating diffusion region is provided at a position that is close to an intersection between the first pixel isolation region and the second pixel isolation region or another of the first pixel isolation region and the second pixel isolation region.

4. The solid-state imaging device according to claim 2, wherein the gate electrode is provided along a side surface of the floating diffusion region.

5. The solid-state imaging device according to claim 4, wherein
the floating diffusion region is formed in a rectangular shape as viewed from the second surface side, and
the gate electrode is provided along the side surface of one or more sides of the rectangular shape of the floating diffusion region.

6. The solid-state imaging device according to claim 1, wherein the gate electrode includes one or more parts extending in the thickness direction of the base body.

7. The solid-state imaging device according to claim 2, wherein the gate electrode is provided between the coupling section and the floating diffusion region.

8. The solid-state imaging device according to claim 2, wherein a separation distance between the coupling section and the floating diffusion region is greater than a separation distance between the gate electrode and the floating diffusion region.

9. The solid-state imaging device according to claim 2, wherein a third surface of the gate electrode on the second surface side is formed at a same position as a fourth surface of the floating diffusion region on the first surface side, or a position on the first surface side with respect to the fourth surface, in the thickness direction of the base body.

10. The solid-state imaging device according to claim 9, wherein an insulator is provided toward the second surface side on the third surface of the gate electrode.

11. The solid-state imaging device according to claim 10, wherein the insulator is embedded at a position corresponding to the third surface, in a groove formed from the second surface of the base body toward the first surface side.

12. The solid-state imaging device according to claim 10, wherein the insulator is formed in a same layer and includes a same insulating material as an interlayer insulating film provided on the second surface of the base body.

13. The solid-state imaging device according to claim 3, wherein
a plurality of the pixels is arranged in the first direction and the second direction with the pixel isolation region interposed therebetween, and
the floating diffusion regions of the respective pixels arranged adjacently in the first direction or the second direction are electrically coupled to each other with a shared coupling section interposed therebetween.
